(19) United States
(12) Patent Application Publication
(10) Pub. No.: US 2025/0261525 A1
(43) Pub. Date: Aug. 14, 2025

(54) ELECTRONIC DEVICE INCLUDING AN ELECTRONIC MODULE AND A MANUFACTURING METHOD THEREOF

(71) Applicant: SAMSUNG DISPLAY CO., LTD., YONGIN-SI (KR)

(72) Inventors: SANGHYUN LIM, Yongin-si (KR); KYOWON KU, Yongin-si (KR); MIYOUNG KIM, Yongin-si (KR); KANGWON LEE, Yongin-si (KR)

(21) Appl. No.: 18/946,177

(22) Filed: Nov. 13, 2024

(30) Foreign Application Priority Data
Feb. 13, 2024 (KR) 10-2024-0020428

(51) Int. Cl. H10K 59/126; G06F 3/041; G06F 3/044; G06F 3/046; G06V 40/13; H10K 59/12; H10K 59/40; H10K 59/80

(52) U.S. Cl. CPC H10K 59/126; G06F 3/0412; G06F 3/0446; G06F 3/046; H10K 59/1201; H10K 59/40; H10K 59/873; G06F 3/04164; G06F 3/04166; G06F 2203/04107; G06F 2203/04111; G06V 40/13

(57) ABSTRACT

An electronic device includes a display panel, a first cover panel disposed under the display panel, and an electronic module disposed under the display panel. The first cover panel includes a first adhesive layer disposed under the display panel, a cushion layer disposed under the first adhesive layer, a magnetic layer disposed under the cushion layer, and a conductive layer disposed under the magnetic layer. The first adhesive layer and the cushion layer together include an opening, and the electronic module is disposed within the opening. A cutting line is defined in the magnetic layer and the conductive layer, surrounding the opening.

### CROSS-REFERENCE TO RELATED APPLICATIONS

This application claims priority under 35 U.S.C. § 119 to Korean Patent Application No. 10-2024-0020428 filed on Feb. 13, 2024, in the Korean Intellectual Property Office, the disclosures of which are incorporated by reference herein in their entireties.

### TECHNICAL FIELD

The present disclosure relates to an electronic device and, more specifically, to an electronic device including an electronic module and a manufacturing method thereof.

### DISCUSSION OF THE RELATED ART

An electronic device may include electronic modules. For example, the electronic device may be a portable terminal or a wearable device, and the electronic modules may include a fingerprint sensor, an antenna module, a camera module, or a battery module. A space in which the electronic modules are to be mounted may be particularly small as it is generally desired that the electronic device be as slim and small as possible, particularly where the electronic device is a wearable device. In addition, a greater number of electronic modules are being included in the electronic device as the electronic device is given greater functionality and higher specifications.

### SUMMARY

An electronic device includes a display panel. A first cover panel is disposed under the display panel. An electronic module is disposed under the display panel. The first cover panel includes a first adhesive layer disposed under the display panel, a cushion layer disposed under the first adhesive layer, a magnetic layer disposed under the cushion layer, and a conductive layer disposed under the magnetic layer. The first adhesive layer and the cushion layer together include an opening, and the electronic module is disposed within the opening. A cutting line is defined in the magnetic layer and the conductive layer, surrounding the opening.

The magnetic layer and the conductive layer may cover the electronic module, in a plan view.

The electronic module may be spaced apart from the magnetic layer and the conductive layer in a thickness direction.

Opposite ends of the cutting line may be spaced apart from each other with a gap interposed therebetween and the opposite ends may face each other.

The cutting line may have a quadrilateral shape, in a plan view.

The opposite ends of the cutting line may be defined on one side of the quadrilateral shape, in a plan view.

The opposite ends of the cutting line may be defined at vertices of the quadrilateral shape, in a plan view.

A first portion and a second portion that extends from the first portion may be defined in the cutting line. The first portion may be defined at one end of the opening when viewed in a first direction, and the second portion may be spaced apart from the opening when viewed in a second direction crossing the first direction.

A first width of the first portion may be greater than a second width of the second portion.

A plurality of third portions adjacent to opposite ends of the second portion may be additionally defined in the cutting line, and the plurality of third portions may be spaced apart from each other in the first direction.

The electronic module may include a fingerprint sensor.

The electronic module may include a speaker or a photo sensor.

In a plan view, the electronic module may overlap the magnetic layer and the conductive layer and might not overlap the first adhesive layer and the cushion layer.

The electronic device may further include a second adhesive layer disposed between the display panel and the electronic module and bonded in a different manner from that of the first adhesive layer. The first adhesive layer may include an optical adhesive material, and the second adhesive layer may include a UV resin.

The display panel may include a display layer and a sensor layer disposed on the display layer. The sensor layer may include a plurality of first electrodes that are arranged in a first direction and that extend in a second direction crossing the first direction, a plurality of second electrodes that are arranged in the second direction and that extend in the first direction, a plurality of first auxiliary electrodes that are arranged in the first direction and that extend in the second direction and overlap the plurality of first electrodes, and a plurality of second auxiliary electrodes that are arranged in the second direction and that extend in the first direction and overlap the plurality of second electrodes.

The cutting line may have a closed-loop shape. The electronic device may further include a second cover panel disposed under the electronic module. The second cover panel may include a first auxiliary adhesive layer disposed between the opening and the cutting line, in a plan view, an auxiliary magnetic layer disposed under the first auxiliary adhesive layer, and an auxiliary conductive layer disposed under the auxiliary magnetic layer.

A total thickness of the first adhesive layer, the cushion layer, and the first auxiliary adhesive layer may be greater than a thickness of the electronic module.

A plurality of slits may be defined in the second cover panel, in a plan view, and the plurality of slits may be formed on side surfaces of the second cover panel.

The second cover panel may further include an auxiliary cushion layer disposed under the first auxiliary adhesive layer.

The cutting line may have a closed-loop shape. The electronic device may further include an electrically conductive bracket and an auxiliary magnetic layer that is disposed on the bracket and that overlaps the electronic module, in a plan view.

The auxiliary magnetic layer may overlap the cover panel, in a plan view.

The electronic device may further include a heat radiating layer disposed on the bracket and under the display panel.

A method for manufacturing an electronic device includes providing a display panel, providing a cover panel, and coupling the display panel and the cover panel to one another. The providing of the cover panel includes coupling a first adhesive layer and a cushion layer to one another, forming an opening in the first adhesive layer and the cushion layer, stacking a magnetic layer and a conductive layer under the cushion layer, attaching, on the first adhesive layer, an adhesive liner having a first auxiliary cutting line formed therein, attaching, under the conductive layer, a protective film having a second auxiliary cutting line formed therein, and forming a cutting line in the cover panel.

In a plan view, the first auxiliary cutting line may be connected with the cutting line in a closed loop.

Opposite ends of the cutting line may be spaced apart from each other with a gap interposed therebetween and the opposite ends may face each other.

In a plan view, the second auxiliary cutting line may be adjacent to the gap and may be spaced apart from the cutting line.

The coupling of the display panel and the cover panel may include removing a portion of the adhesive liner based on the first auxiliary cutting line and the cutting line and bonding a portion of the first adhesive layer from which the adhesive liner is removed and the display panel to one another.

The method may further include delaminating and bending a portion of the cover panel along the cutting line, attaching an electronic module under the display panel, removing the rest of the adhesive liner, unbending the portion of the cover panel such that the electronic module is accommodated in the opening, and bonding the rest of the first adhesive layer and the display panel to one another.

### BRIEF DESCRIPTION OF THE FIGURES

The above and other objects and features of the present disclosure will become apparent by describing in detail embodiments thereof with reference to the accompanying drawings.

FIG. 1 is a block diagram of an electronic device according to an embodiment of the present disclosure.

FIG. 2 is a perspective view of the electronic device according to an embodiment of the present disclosure.

FIG. 3 is a schematic cross-sectional view of the electronic device according to an embodiment of the present disclosure.

FIG. 4 is a schematic cross-sectional view of a display panel according to an embodiment of the present disclosure.

FIG. 5 is a view illustrating an operation of the electronic device according to an embodiment of the present disclosure.

FIG. 6 is a cross-sectional view of the display panel according to an embodiment of the present disclosure.

FIG. 7 is a plan view of a sensor layer according to an embodiment of the present disclosure.

FIG. 8 is an enlarged plan view illustrating one sensing unit according to an embodiment of the present disclosure.

FIG. 9A is a plan view illustrating a first conductive layer of the sensing unit according to an embodiment of the present disclosure.

FIG. 9B is a plan view illustrating a second conductive layer of the sensing unit according to an embodiment of the present disclosure.

FIG. 9C is a cross-sectional view of the sensor layer taken along line I-I′ illustrated in each of FIGS. 9A and 9B.

FIG. 10A is a plan view illustrating a first conductive layer of a sensing unit according to an embodiment of the present disclosure.

FIG. 10B is a plan view illustrating a second conductive layer of the sensing unit according to an embodiment of the present disclosure.

FIG. 10C is a cross-sectional view of the sensor layer taken along line A-A′ illustrated in each of FIGS. 10A and 10B according to an embodiment of the present disclosure.

FIG. 11 is a view illustrating an operation of a sensor driver according to an embodiment of the present disclosure.

FIG. 12 is a view illustrating an operation of the sensor driver according to an embodiment of the present disclosure.

FIGS. 13A and 13B are views illustrating a first mode according to an embodiment of the present disclosure.

FIG. 14 is a view illustrating the first mode according to an embodiment of the present disclosure.

FIG. 15 is a view illustrating a second mode according to an embodiment of the present disclosure.

FIG. 16A is a view illustrating the second mode according to an embodiment of the present disclosure.

FIG. 16B is a view illustrating the second mode based on sensing units according to an embodiment of the present disclosure.

FIG. 17 is a cross-sectional view of the electronic device according to an embodiment of the present disclosure.

FIG. 18 is a flowchart illustrating a method of manufacturing the electronic device according to an embodiment of the present disclosure.

FIG. 19 is a flowchart illustrating a method of providing a cover panel according to an embodiment of the present disclosure.

FIG. 20A is a plan view illustrating an adhesive liner according to an embodiment of the present disclosure.

FIG. 20B is a plan view of an adhesive layer and a cushion layer according to an embodiment of the present disclosure.

FIG. 20C is a plan view of a magnetic layer and a conductive layer according to an embodiment of the present disclosure.

FIG. 20D is a plan view of a protective film according to an embodiment of the present disclosure.

FIG. 21 is a cross-sectional view of a preliminary cover panel taken along a line corresponding to II-II′ in FIG. 20B according to an embodiment of the present disclosure.

FIG. 22 is a cross-sectional view of the preliminary cover panel taken along a line corresponding to III-III′ in FIG. 20B according to an embodiment of the present disclosure.

FIG. 23A is a cross-sectional view illustrating part of a step of coupling the display panel and the cover panel according to an embodiment of the present disclosure.

FIG. 23B is a cross-sectional view illustrating part of the method of manufacturing the electronic device according to an embodiment of the present disclosure.

FIG. 23C is a cross-sectional view illustrating part of the method of manufacturing the electronic device according to an embodiment of the present disclosure.

FIG. 24 is a plan view illustrating a cover panel according to an embodiment of the present disclosure.

FIG. 25 is a cross-sectional view of an electronic device taken along a line corresponding to IV-IV′ in FIG. 24 according to an embodiment of the present disclosure.

FIG. 26A is a plan view illustrating a cover panel according to an embodiment of the present disclosure.

FIG. 26B is a plan view illustrating a cover panel according to an embodiment of the present disclosure.

FIG. 27 is a plan view of a cover panel according to an embodiment of the present disclosure.

FIG. 28 is a plan view of a first cover panel according to an embodiment of the present disclosure.

FIG. 29 is a cross-sectional view of an electronic device according to an embodiment of the present disclosure.

FIG. 30 is a plan view illustrating a second cover panel according to an embodiment of the present disclosure.

FIG. 31A is a cross-sectional view of a second cover panel according to an embodiment of the present disclosure.

FIG. 31B is a cross-sectional view of a second cover panel according to an embodiment of the present disclosure.

FIG. 31C is a cross-sectional view of a second cover panel according to an embodiment of the present disclosure.

FIG. 32 is a cross-sectional view of an electronic device according to an embodiment of the present disclosure.

FIG. 33 is a plan view illustrating a bracket according to an embodiment of the present disclosure.

FIG. 34 is a cross-sectional view of an electronic device taken along a line corresponding to V-V′ in FIG. 33 according to an embodiment of the present disclosure.

FIG. 35 is a cross-sectional view of the electronic device taken along a line corresponding to VI-VI′ in FIG. 33 according to an embodiment of the present disclosure.

### DETAILED DESCRIPTION

In this specification, when it is mentioned that a component (or, an area, a layer, a part, etc.) is referred to as being “on”, “connected to” or “coupled to” another component, this means that the component may be directly on, connected to, or coupled to the other component or a third component may be present therebetween.

Identical reference numerals may refer to identical components throughout the disclosure and the drawings. Additionally, while each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like. As used herein, the term “and/or” includes all of one or more combinations defined by related components.

Terms such as first, second, and the like may be used to describe various components, but the components should not necessarily be limited by the terms. The terms may be used for distinguishing one component from other components. For example, without departing the scope of the present disclosure, a first component may be referred to as a second component, and similarly, the second component may also be referred to as the first component. The terms of a singular form may include plural forms unless otherwise specified.

In addition, terms such as “below”, “under”, “above”, and “over” are used to describe a relationship of components illustrated in the drawings. The terms are relative concepts and are described based on directions illustrated in the drawing.

It should be understood that terms such as “comprise”, “include”, and “have”, when used herein, specify the presence of stated features, numbers, steps, operations, components, parts, or combinations thereof, but do not necessarily preclude the presence or addition of one or more other features, numbers, steps, operations, components, parts, or combinations thereof.

Hereinafter, embodiments of the present disclosure will be described with reference to the accompanying drawings.

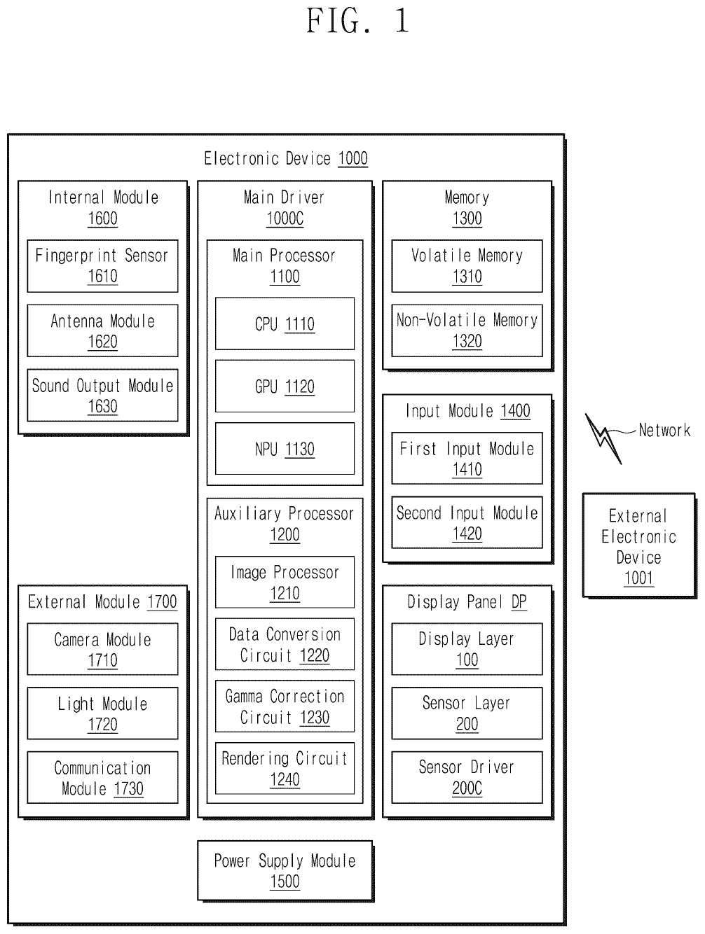

FIG. 1 is a block diagram of an electronic device according to an embodiment of the present disclosure.

Referring to FIG. 1, the electronic device 1000 may output various pieces of information through a display panel DP within an operating system. When a main driver 1000C executes an application stored in a memory 1300, the display panel DP may provide application information to a user through a display layer 100. The main driver 1000C may be referred to as a host processor.

The main driver 1000C may obtain an external input through an input module 1400 and may execute an application corresponding to the external input. For example, when the user selects a camera icon displayed on the display layer 100, the main driver 1000C may obtain a user input through a sensor layer 200 and a sensor driver 200C and may activate a camera module 1710. The main driver 1000C may transfer image data corresponding to a photographed image obtained through the camera module 1710 to the display panel DP. The display panel DP may display an image corresponding to the photographed image through the display layer 100.

In an example, when personal information authentication is executed on the display panel DP, a fingerprint sensor 1610 may obtain input fingerprint information as input data. The main driver 1000C may compare the input data obtained through the fingerprint sensor 1610 with authentication data stored in the memory 1300 and may execute an application depending on the comparison result. The display panel DP may display information executed depending on the logic of the application through the display layer 100.

In an example, when a music streaming icon displayed on the display panel DP is selected, the main driver 1000C may obtain a user input through the sensor layer 200 and the sensor driver 200C and may activate a music streaming application stored in the memory 1300. When a music execution command is input in the music streaming application, the main driver 1000C may activate a sound output module 1630 and may provide sound information corresponding to the music execution command to the user.

Hereinafter, components of the electronic device 1000 will be described in detail. Some of the components of the electronic device 1000 that will be described below may be integrated and provided as one component, or one component may be divided into two or more components.

The electronic device 1000 may communicate with an external electronic device 1001 through a network (e.g., a short-range wireless communication network or a long-range wireless communication network). According to an embodiment, the electronic device 1000 may include the processor 1000, the memory 1300, the input module 1400, the display panel DP, a power supply module 1500, an internal module 1600, and an external module 1700. According to an embodiment, at least one of the above-described components may be omitted from the electronic device 1000, or one or more other components may be added to the electronic device 1000. According to an embodiment, some of the above-described components (e.g., the fingerprint sensor 1610, an antenna module 1620, and the sound output module 1630) may be integrated into another component (e.g., the display panel DP).

The main driver 1000C may execute software to control at least one other component (e.g., a hardware or software component) of the electronic device 1000 connected to the main driver 1000C and may perform various data processing or computation. According to an embodiment, as at least a portion of the data processing or computation, the main driver 1000C may store commands or data received from another component (e.g., the input module 1400, the fingerprint sensor 1610, or a communication module 1730) in a volatile memory 1310, may process the commands or data stored in the volatile memory 1310, and may store result data in a non-volatile memory 1320.

The main driver 1000C may include a main processor 1100 and an auxiliary processor 1200. The main processor 1100 may include of a central processing unit (CPU) 1110 and/or an application processor. The main processor 1100 may further include at least one graphic processing unit (GPU) 1120, a communication processor (CP), and/or an image signal processor (ISP). The main processor 1100 may further include a neural processing unit (NPU) 1130. The neural processing unit may be a processor specialized in processing an artificial intelligence model, and the artificial intelligence model may be generated through machine learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination of two or more thereof, but is not necessarily limited thereto. Additionally or alternatively, the artificial intelligence model may include a software structure in addition to the hardware structure. At least two of the processing units and the processors described above may be implemented as one integrated component (e.g., a single chip), or may be implemented as independent components (e.g., a plurality of chips).

The auxiliary processor 1200 may include an image processor 1210, a data conversion circuit 1220, a gamma correction circuit 1230, and a rendering circuit 1240. The image processor 1210 may convert the data format of image data and may output the image data.

The data conversion circuit 1220 may receive image data from a driving controller that drives the display layer 100 and may compensate for the image data depending on characteristics of the electronic device 1000 or the user's settings such that an image is displayed with desired luminance, or may convert the image data to reduce power consumption or compensate for image persistence. The gamma correction circuit 1230 may convert image data or a gamma reference voltage such that an image displayed on the electronic device 1000 has desired gamma characteristics. The rendering circuit 1240 may receive image data from the driving controller and may render the image data in consideration of a pixel arrangement of the display layer 100 applied to the electronic device 1000. The data conversion circuit 1220, the gamma correction circuit 1230, and/or the rendering circuit 1240 may be integrated into another component (e.g., the main processor 1100 or the driving controller). The data conversion circuit 1220, the gamma correction circuit 1230, and/or the rendering circuit 1240 may be integrated into a data driver.

The memory 1300 may store various data used by at least one component (e.g., the main driver 1000C) of the electronic device 1000 and input data or output data for commands related to the various data. The memory 1300 may include the volatile memory 1310 and/or the non-volatile memory 1320.

The input module 1400 may receive a command or data to be used for a component (e.g., the main driver 1000C, the sensor layer 200, or the sound output module 1630) of the electronic device 1000 from outside the electronic device 1000 (e.g., the user or the external electronic device 1001).

The input module 1400 may include a first input module 1410, to which a command or data is input from the user, and a second input module 1420, to which a command or data is input from the external electronic device 1001. The first input module 1410 may include a microphone, a mouse, a keyboard (e.g., a button), or a stylus/pen (e.g., a passive pen or an active pen). The second input module 1420 may support a specified protocol for wired or wireless connection with the external electronic device 1001. According to an embodiment, the second input module 1420 may include a high definition multimedia interface (HDMI), a universal serial bus (USB) interface, an SD card interface, or an audio interface. The second input module 1420 may include a connector for physical connection with the external electronic device 1001, for example, an HDMI connector, a USB connector, an SD card connector, or an audio connector (e.g., a headphone connector).

The display panel DP may visually provide information to the user. The display panel DP may include the display layer 100, the sensor layer 200, and the sensor driver 200C. The display panel DP may further include a window, a chassis, or a bracket for protection of the display layer 100. The display panel DP may further include an emission driving circuit and a voltage generator.

The sensor layer 200 may generate a data value corresponding to coordinate information of an input by a part of the user's body or an input by a pen. The sensor layer 200 may generate the amount of change in capacitance caused by the input as the data value. The sensor layer 200 may sense an input by a passive pen, or may transmit/receive data with an active pen.

The power supply module 1500 may supply power to components of the electronic device 1000. The power supply module 1500 may include a battery that charges a power voltage. The battery may include a primary cell that is not rechargeable, a secondary cell that is rechargeable, or a fuel cell. The power supply module 1500 may include a power management integrated circuit (PMIC). The PMIC may supply power optimized for each of the modules described above and modules to be described below. The PMIC may supply power optimized for each of the components described above and components to be described below. The power supply module 1500 may include a wireless power transmission/reception element electrically connected with the battery. The wireless power transmission/reception element may include a plurality of antenna radiators having a coil shape.

The electronic device 1000 may further include the internal module 1600 and the external module 1700. The internal module 1600 may include the fingerprint sensor 1610, the antenna module 1620, and the sound output module 1630. The external module 1700 may include the camera module 1710, a light module 1720, and the communication module 1730.

The fingerprint sensor 1610 may generate a data value corresponding to a fingerprint of the user. The fingerprint sensor 1610 may include one of a fingerprint sensor of an ultrasonic type, a fingerprint sensor of an optical type, and a fingerprint sensor of a capacitive type.

The antenna module 1620 may include one or more antennas for transmitting a signal or power to the outside or receiving a signal or power from the outside. According to an embodiment, the communication module 1730 may transmit or receive a signal with the external electronic device 1001 through an antenna appropriate for a communication scheme. An antenna pattern of the antenna module 1620 may be integrated into one component (e.g., the display layer 100 or the sensor layer 200) of the display panel DP.

The sound output module 1630 may be a device for outputting a sound signal to the outside of the electronic device 1000. For example, the sound output module 663 may include a speaker and a receiver. The speaker may be used for general purposes such as playing multimedia and playing record, and the receiver may be used only for incoming calls. According to an embodiment, the receiver may be integrally formed with the speaker, or may be formed separately from the speaker. A sound output pattern of the sound output module 1630 may be integrated into the display panel DP.

The camera module 1710 may take a still image and a video. According to an embodiment, the camera module 1710 may include one or more lenses, an image sensor, or an image signal processor. The camera module 1710 may further include an infrared camera capable of measuring a presence or absence of the user, the location of the user, and a gaze of the user.

The light module 1720 may provide light. The light module 1720 may include a light emitting diode or a xenon lamp. The light module 1720 may operate in conjunction with the camera module 1710, or may operate independently of the camera module 1710.

The communication module 1730 may support establishing a wired or wireless communication channel between the electronic device 1000 and the external electronic device 1001 and may support performing communication via the established communication channel. The communication module 1730 may include either or both of a wireless communication module, such as a cellular communication module, a short-range wireless communication module, or a global navigation satellite system (GNSS) communication module, and a wired communication module, such as a local area network (LAN) communication module or a power line communication module. The communication module 1730 may communicate with the external electronic device 1001 through a short-range communication network, such as Bluetooth, WiFi, or infrared data association (IrDA), or a long-range communication network, such as a cellular network, the Internet, or a computer network (e.g., LAN or WAN). The above-described various types of communication modules 1730 may be implemented with one chip, or may be implemented with separate chips, respectively.

The internal module 1600 and the external module 1700 may be used to control an operation of the display panel DP in conjunction with the main driver 1000C.

The main driver 1000C may output a command or data to the display layer 100, the sound output module 1630, the camera module 1710, or the light module 1720, based on input data received from the sensor layer 200. For example, the main driver 1000C may generate image data corresponding to input data applied through a mouse or a pen and may output the generated image data to the display layer 100, or the main driver 1000C may generate command data corresponding to the input data applied through the mouse or the pen and may output the generated command data to the camera module 1710 or the light module 1720. When input data is not received from the input module 1400 for a certain period of time, the main driver 1000C may switch an operating mode of the electronic device 1000 to a low-power mode or a sleep mode to reduce power consumed by the electronic device 1000.

Some of the components described above may be connected through an inter-peripheral communication method, for example, a bus, a general purpose input/output (GPIO), a serial peripheral interface (SPI), a mobile industry processor interface (MIPI), or a ultra path interconnect (UPI) link and may exchange signals (e.g., commands or data) with one another. The main driver 1000C may communicate with the display panel DP through an agreed interface. For example, the main driver 1000C may use one of the above-described communication schemes and is not necessarily limited to the above-described communication schemes.

The electronic device 1000, according to various embodiments disclosed herein, may include various forms of devices. For example, the electronic device 1000 may include a portable communication device (e.g., a smart phone), a computer device, a portable multimedia device, a portable medical device, a camera, a wearable device, and/or a home appliance. The electronic device 1000 according to the present disclosure is not necessarily limited to the aforementioned devices.

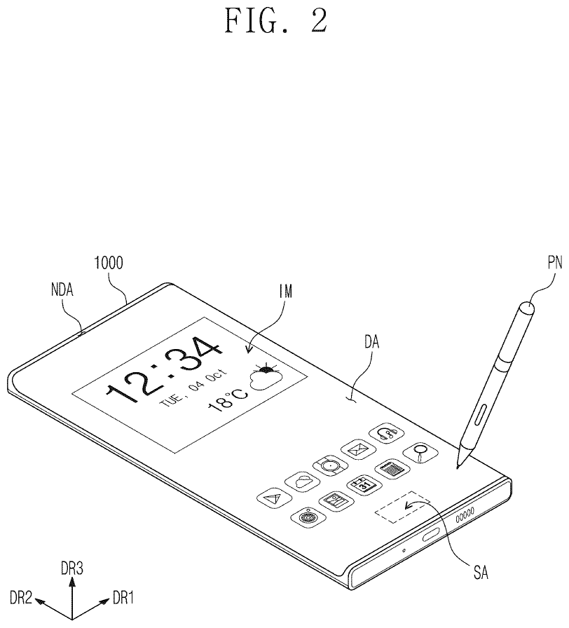

FIG. 2 is a perspective view of the electronic device according to an embodiment of the present disclosure.

Referring to FIG. 2, the electronic device 1000 may sense an input by an input device PN. The electronic device 1000 may be a device activated depending on an electrical signal. For example, the electronic device 1000 may be a mobile phone, a tablet computer, a car navigation unit, a game machine, or a wearable device, but is not necessarily limited thereto. In FIG. 2, the electronic device 1000 is illustrated as a mobile phone (e.g., smartphone).

The electronic device 1000 may include an active area DA and a peripheral area NDA defined therein.

The active area DA may include a plane defined by a first direction DR1 and a second direction DR2. The electronic device 1000 may display an image IM through the active area DA in a third direction DR3 that crosses the first direction DR1 and the second direction DR2. A sensing area SA may be defined in the active area DA. The electronic device 1000 may recognize biometric information of the user through the sensing area SA.

The peripheral area NDA may surround the periphery of the active area DA.

The electronic device 1000 may sense inputs applied from outside the electronic device 1000. The external inputs may include various types of external inputs such as a part of the user's body, light, heat, or pressure. The external inputs may be referred to as a second input.

The electronic device 1000 illustrated in FIG. 2 may sense an input by a touch of the user and an input by the input device PN. The input device PN may mean a device other than the user's body. The input by the input device PN may be referred to as a first input. For example, the input device PN may be an active electrostatic (AES) pen, an electromagnetic resonance (EMR) pen, a stylus pen, a touch pen, or an electronic pen. Hereinafter, it will be exemplified that the input device PN is an electromagnetic resonance (EMR) pen. The input device PN may be referred to as a pen PN.

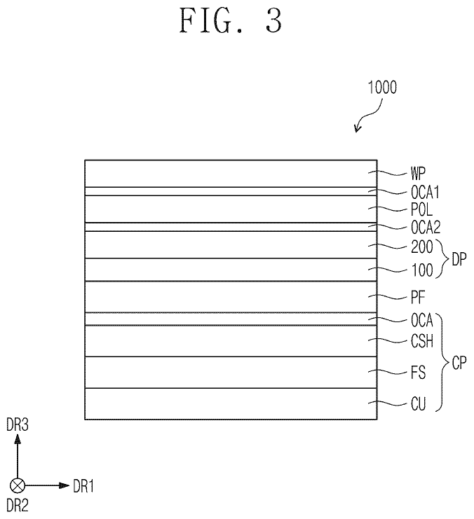

FIG. 3 is a schematic cross-sectional view of the electronic device according to an embodiment of the present disclosure.

Referring to FIG. 3, the electronic device 1000 may include a window WP, a plurality of adhesive layers OCA1, OCA2, and OCA, an anti-reflective layer POL, the display panel DP, a protective layer PF, and a cover panel CP.

The window WP may form the exterior of the electronic device 1000. The window WP may be a component that protects internal components of the electronic device 1000 from external impact and substantially provides the active area DA (refer to FIG. 2) of the electronic device 1000. For example, the window WP may include a glass substrate, a sapphire substrate, or a plastic film. The window WP may have a single-layer structure or a multi-layer structure. For example, the window WP may have a stacked structure of a plurality of plastic films coupled through an adhesive, or may have a stacked structure of a glass substrate and a plastic film coupled through an adhesive.

The first adhesive layer OCA1 may be disposed under the window WP. The window WP and the anti-reflective layer POL may be coupled by the first adhesive layer OCA1. The first adhesive layer OCA1 may include a conventional adhesive or sticky substance. For example, the first adhesive layer OCA1 may be an optically clear adhesive film, an optically clear resin, or a pressure sensitive adhesive film.

The anti-reflective layer POL may be disposed under the window WP. The anti-reflective layer POL may decrease the reflectance of natural light (or, sunlight) incident from above the window WP.

The anti-reflective layer POL, according to an embodiment of the present disclosure, may include a phase retarder and a polarizer. The phase retarder may be of a film type or a liquid-crystal coating type and may include a λ/2 phase retarder (half-wave plate) and/or a λ/4 phase retarder (quarter-wave plate). The polarizer may be of a film type or a liquid-crystal coating type. The polarizer of a film type may include a stretchable synthetic resin film, and the polarizer of a liquid-crystal coating type may include liquid crystals arranged in a certain arrangement. The phase retarder and the polarizer may further include a protective film. The phase retarder and the polarizer themselves or the protective film may be defined as a base layer of the anti-reflective layer POL.

The second adhesive layer OCA2 may be disposed under the anti-reflective layer POL. The anti-reflective layer POL and the display panel DP may be coupled by the second adhesive layer OCA2. The second adhesive layer OCA2 may include substantially the same material as the first adhesive layer OCA1.

The display panel DP may include the display layer 100 and the sensor layer 200.

The sensor layer 200 may be disposed under the anti-reflective layer POL. The sensor layer 200 may obtain coordinate information of an external input. The sensor layer 200 may sense an input by the input device PN (refer to FIG. 2). The sensor layer 200 according to an embodiment of the present disclosure may be directly disposed on one surface of the display layer 100. For example, the sensor layer 200 may be integrated with the display layer 100 in an on-cell type. The sensor layer 200 may be manufactured with the display layer 100 by a continuous process. However, without necessarily being limited thereto, the sensor layer 200 may be manufactured by a separate process and may be bonded to the display layer 100.

The display layer 100 may be disposed under the sensor layer 200. The display layer 100 may be a component that substantially generates the image IM (refer to FIG. 2). The display layer 100 may be an emissive display layer, but is not necessarily particularly limited thereto. For example, the display layer 100 may include an organic light emitting display layer, a quantum-dot display layer, a micro-LED display layer, or a nano-LED display layer. An emissive layer of the organic light emitting display layer may include an organic luminescent material. An emissive layer of the quantum-dot display layer may include quantum dots and quantum rods. An emissive layer of the micro-LED display layer may include a micro-LED. An emissive layer of the nano-LED display layer may include a nano-LED.

The protective layer PF may be disposed under the display panel DP. The protective layer PF may protect the lower surface of the display layer 100. The protective layer PF may include polyethylene terephthalate (PET). However, the material of the protective layer PF is not necessarily particularly limited thereto.

The cover panel CP may be disposed under the protective layer PF. The cover panel CP may include the first adhesive layer OCA, a cushion layer CSH, a magnetic layer FS, and a conductive layer CU.

The first adhesive layer OCA may attach the cushion layer CSH and the protective layer PF to each other. The first adhesive layer OCA1 may include a conventional adhesive or sticky substance. For example, the first adhesive layer OCA may be an optically clear adhesive film, an optically clear resin, or a pressure sensitive adhesive film.

The cushion layer CSH may be disposed under the first adhesive layer OCA. The cushion layer CSH may include an embo (e.g., embossed) sheet and a cushion sheet.

The embo sheet may be a colored sheet. For example, the embo sheet may be black. The embo sheet may absorb light incident to the cushion layer CSH.

The cushion sheet may alleviate pressure applied from the outside. The cushion sheet may include a sponge, expanded foam, or a urethane resin. The cushion sheet may be thicker than the embo sheet.

The magnetic layer FS may be disposed under the cushion layer CSH. The magnetic layer FS may reflect a magnetic field that transmits through the display panel DP. Due to this, the magnetic field reaching the magnetic layer FS may be reflected upward. Accordingly, the magnetic layer FS may prevent signal interference from the outside. The magnetic layer FS may include a magnetic material containing iron oxide, such as ferrite.

The conductive layer CU may be disposed under the magnetic layer FS. The conductive layer CU may be electrically conductive. The conductive layer CU may shield a magnetic field passing through the magnetic layer FS such that the magnetic field is not leaked to the outside, for example, below the conductive layer CU. In addition, the conductive layer CU may block a magnetic field generated from a component (e.g., an antenna) disposed under the conductive layer CU such that the magnetic field does not reach the display panel DP. The conductive layer CU may include aluminum, copper, or a copper alloy. For example, the conductive layer CU may be a copper (Cu) tape. However, the present disclosure is not necessarily limited thereto. A ground voltage may be applied to the conductive layer CU. However, this is illustrative, and the conductive layer CU may be floated.

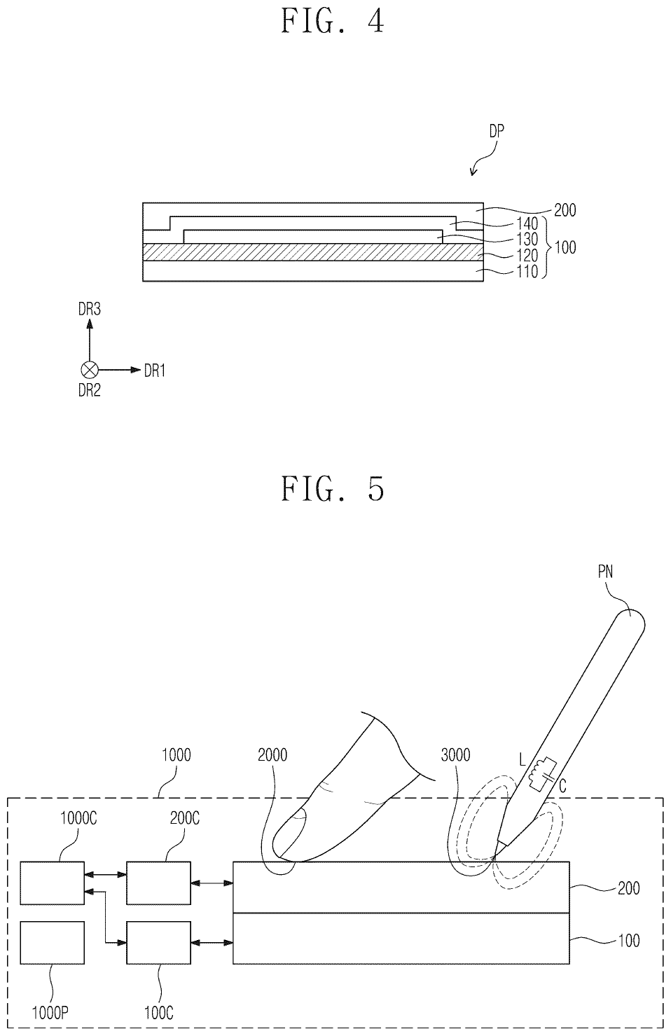

FIG. 4 is a schematic cross-sectional view of the display panel according to an embodiment of the present disclosure.

Referring to FIG. 4, the display panel DP may include the display layer 100 and the sensor layer 200.

The display layer 100 may include a base layer 110, a circuit layer 120, a light emitting element layer 130, and an encapsulation layer 140.

The base layer 110 may be an element that provides a base surface on which the circuit layer 120 is disposed. The base layer 110 may have a multi-layer structure or a single-layer structure. The base layer 110 may be a glass substrate, a metal substrate, a silicon substrate, or a polymer substrate, but is not necessarily particularly limited thereto.

The circuit layer 120 may be disposed on the base layer 110. The circuit layer 120 may include an insulating layer, a semiconductor pattern, a conductive pattern, and a signal line. An insulating layer, a semiconductor layer, and a conductive layer may be formed on the base layer 110 by a process such as coating or deposition and may be selectively subjected to patterning by performing a photolithography process a plurality of times.

The light emitting element layer 130 may be disposed on the circuit layer 120. The light emitting element layer 130 may include light emitting elements. For example, the light emitting element layer 130 may include an organic luminescent material, an inorganic luminescent material, an organic-inorganic luminescent material, a quantum dot, a quantum rod, a micro LED, or a nano LED.

The encapsulation layer 140 may be disposed on the light emitting element layer 130. The encapsulation layer 140 may protect the light emitting element layer 130 from foreign matter such as moisture, oxygen, and dust particles.

The sensor layer 200 may be disposed on the display layer 100. The sensor layer 200 may sense an external input applied from the outside. The sensor layer 200 may be an integrated sensor continuously formed in a process of manufacturing the display layer 100. Alternatively, the sensor layer 200 may be an external sensor attached to the display layer 100. The sensor layer 200 may be referred to as a sensor, an input sensing layer, an input sensing panel, or an electronic device for sensing input coordinates.

According to an embodiment of the present disclosure, the sensor layer 200 may sense both an input by a passive input means such as a part of the user's body and an input by the input device PN (refer to FIG. 2) that generates a magnetic field having a certain resonant frequency.

FIG. 5 is a view illustrating an operation of the electronic device according to an embodiment of the present disclosure.

Referring to FIG. 5, the electronic device 1000 may include the display layer 100, the sensor layer 200, a display driver 100C, the sensor driver 200C, the main driver 1000C, and a power circuit 1000P.

The sensor layer 200 may sense a first input 2000 or a second input 3000 applied from the outside. Each of the first input 2000 and the second input 3000 may be an input capable of providing a change in the capacitance of the sensor layer 200 or an input capable of causing an induced current in the sensor layer 200. For example, the first input 2000 may be a passive type input such as a part of the user's body. The second input 3000 may be an input by the pen PN or an input by an RFIC tag. For example, the pen PN may be a pen of a passive type or a pen of an active type.

In an embodiment of the present disclosure, the pen PN may be a device that generates a magnetic field having a certain resonant frequency. The pen PN may be configured to transmit an output signal based on an electromagnetic resonance scheme. The pen PN may be referred to as an input device, an input pen, a magnetic pen, a stylus, or an electromagnetic resonance pen.

The pen PN may include an RLC resonance circuit, and the RLC resonance circuit may include an inductor L and a capacitor C. In an embodiment of the present disclosure, the RLC resonance circuit may be a variable resonance circuit that varies the resonant frequency. In this case, the inductor L may be a variable inductor, and/or the capacitor C may be a variable capacitor. However, the present disclosure is not necessarily particularly limited thereto.

The inductor L generates a current by a magnetic field formed in the sensor layer 200. However, the present disclosure is not necessarily particularly limited thereto. For example, when the pen PN operates in an active type, the pen PN may generate a current even though a magnetic field is not provided to the pen PN from the outside. The generated current is transferred to the capacitor C. The capacitor C charges the current input from the inductor L and discharges the charged current to the inductor L. Thereafter, the inductor L may emit a magnetic field having a resonant frequency. An induced current may flow in the sensor layer 200 by the magnetic field emitted from the pen PN. The induced current may be transferred to the sensor driver 200C as a reception signal (or, a sensing signal or a signal).

The main driver 1000C may control overall operation of the electronic device 1000. For example, the main driver 1000C may control operations of the display driver 100C and the sensor driver 200C. The main driver 1000C may include at least one microprocessor and may further include a graphic controller. The main driver 1000C may be referred to as an application processor, a central processing unit, or a main processor.

The display driver 100C may drive the display layer 100. The display driver 100C may receive image data and a control signal from the main driver 1000C. The control signal may include various signals. For example, the control signal may include an input vertical synchronization signal, an input horizontal synchronization signal, a main clock, and a data enable signal.

The sensor driver 200C may drive the sensor layer 200. The sensor driver 200C may receive a control signal from the main driver 1000C. The control signal may include a clock signal of the sensor driver 200C. In addition, the control signal may further include a mode determination signal for determining a driving mode of the sensor driver 200C and the sensor layer 200.

The sensor driver 200C may be implemented with an integrated circuit (IC) and may be electrically connected with the sensor layer 200. For example, the sensor driver 200C may be directly mounted on a certain area of the display panel DP or may be mounted on a separate printed circuit board using a chip on film (COF) method and may be electrically connected with the sensor layer 200.

The sensor driver 200C and the sensor layer 200 may selectively operate in a first mode or a second mode. For example, the first mode may be a mode for sensing a touch input, for example, the first input 2000. The second mode may be a mode for sensing an input by the pen PN, for example, the second input 3000. The first mode may be referred to as a touch sensing mode, and the second mode may be referred to as a pen sensing mode.

Switching between the first mode and the second mode may be performed in various ways. For example, the sensor driver 200C and the sensor layer 200 may be driven in the first mode and the second mode in a time-division manner and may sense the first input 2000 and the second input 3000. Alternatively, the switching between the first mode and the second mode may be performed by the user's selection or the user's specific action, or by activating or deactivating a specific application, one of the first mode and the second mode may be activated or deactivated or the driving mode may be switched from one mode to the other mode. In another case, while the sensor driver 200C and the sensor layer 200 alternately operate in the first mode and the second mode, when the first input 2000 is sensed, the sensor driver 200C and the sensor layer 200 may remain in the first mode, and when the second input 3000 is sensed, the sensor driver 200C and the sensor layer 200 may remain in the second mode.

The sensor driver 200C may calculate coordinate information of an input based on a signal received from the sensor layer 200 and may provide a coordinate signal having the coordinate information to the main driver 1000C. The main driver 1000C executes an operation corresponding to a user input, based on the coordinate signal. For example, the main driver 1000C may operate the display driver 100C such that a new application image is displayed on the display layer 100.

The power circuit 1000P may include a power management integrated circuit (PMIC). The power circuit 1000P may generate a plurality of driving voltages for driving the display layer 100, the sensor layer 200, the display driver 100C, and the sensor driver 200C. For example, the plurality of driving voltages may include a gate high-voltage, a gate low-voltage, a first driving voltage (e.g., an ELVSS voltage), a second driving voltage (e.g., an ELVDD voltage), an initialization voltage, and the like, but are not necessarily particularly limited to the examples. The power circuit 1000P may be included in the power supply module 1500 (refer to FIG. 1).

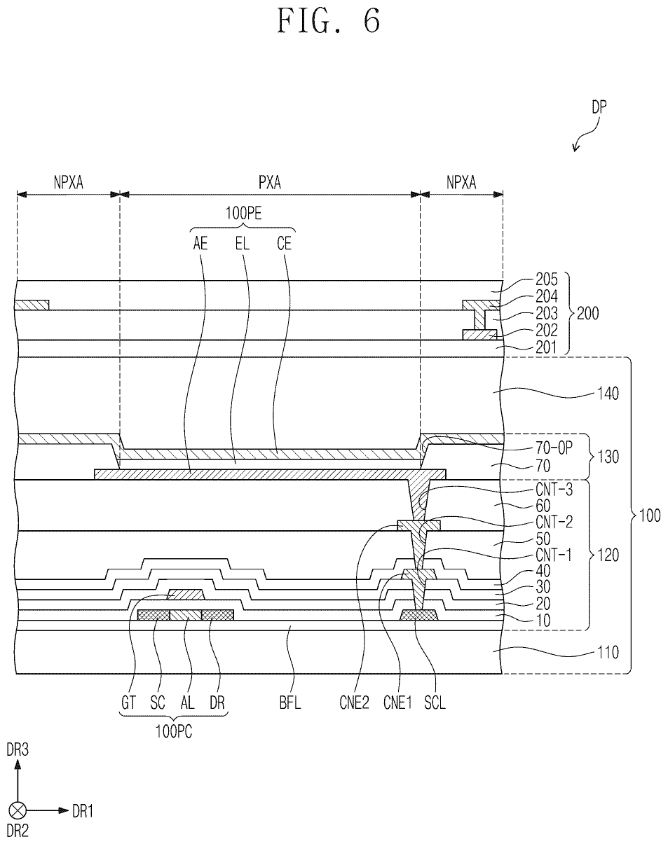

FIG. 6 is a cross-sectional view of the display panel according to an embodiment of the present disclosure. In describing FIG. 6, the components described with reference to FIG. 4 will be assigned with the identical reference numerals, and to the extent that an element is not described in detail with respect to this figure, it may be understood that the element is at least similar to a corresponding element that has been described elsewhere within the present disclosure.

Referring to FIG. 6, at least one buffer layer BFL is formed on the upper surface of the base layer 110. The buffer layer BFL may increase the coupling force between the base layer 110 and a semiconductor pattern. The buffer layer BFL may be formed of multiple layers. Alternatively, the display layer 100 may further include a barrier layer. The buffer layer BFL may include silicon oxide, silicon nitride, and/or silicon oxy nitride. For example, the buffer layer BFL may include a structure in which silicon oxide layers and silicon nitride layers are alternately stacked one above another.

The semiconductor pattern SC, AL, DR, and SCL may be disposed on the buffer layer BFL. The semiconductor pattern SC, AL, DR, and SCL may include poly silicon. However, without necessarily being limited thereto, the semiconductor pattern SC, AL, DR, and SCL may include amorphous silicon, low-temperature polycrystalline silicon, or oxide semiconductor.

FIG. 6 illustrates only a portion of the semiconductor pattern SC, AL, DR, and SCL, and the semiconductor pattern may be additionally disposed within other areas. The semiconductor pattern SC, AL, DR, and SCL may be arranged over pixels according to a specific rule. The semiconductor pattern SC, AL, DR, and SCL may have different electrical properties depending on whether doping is performed or not. The semiconductor pattern SC, AL, DR, and SCL may include first areas SC, DR, and SCL having a high conductivity and a second area AL having a low conductivity. The first areas SC, DR, and SCL may be doped with an N-type dopant or a P-type dopant. A P-type transistor may include a doped area that is doped with a P-type dopant, and an N-type transistor may include a doped area that is doped with an N-type dopant. The second area AL may be an un-doped area, or may be an area more lightly doped than the first areas.

The first areas SC, DR, and SCL may have a higher conductivity than the second area AL and may substantially serve as electrodes or signal lines. The second area AL may substantially correspond to an active area AL (or, a channel) of a transistor 100PC. For example, one portion AL of the semiconductor pattern SC, AL, DR, and SCL may be the active area AL of the transistor 100PC, another portion SC or DR of the semiconductor pattern SC, AL, DR, and SCL may be a source area SC or a drain area DR of the transistor 100PC, and the other portion SCL of the semiconductor pattern SC, AL, DR, and SCL may be a connecting electrode or a connecting signal line SCL.

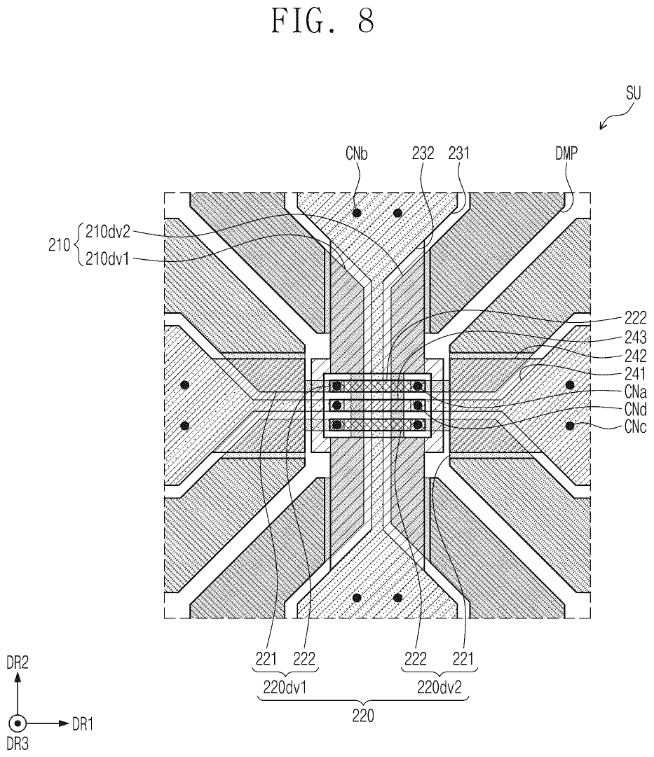

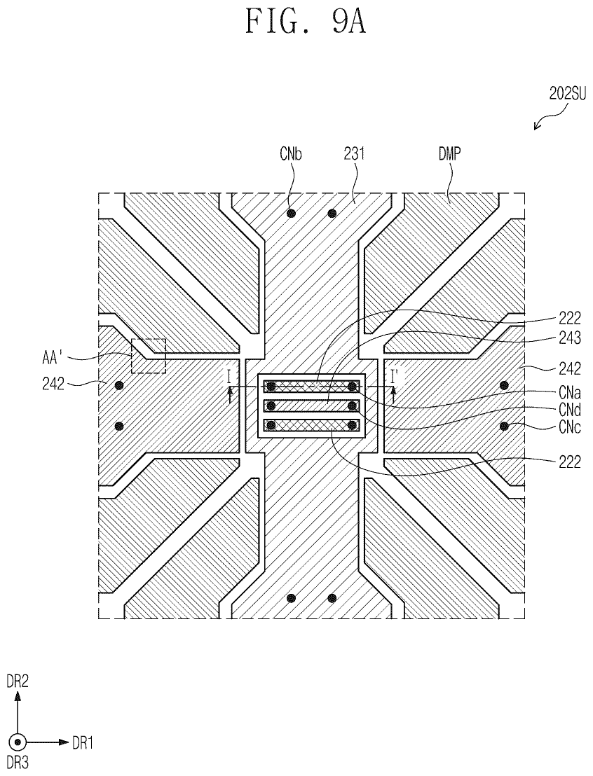

Each of the pixels may have an equivalent circuit including seven transistors, one capacitor, and a light emitting element, and the equivalent circuit of the pixel may be modified in various forms. In FIG. 8, one transistor 100PC and one light emitting element 100PE included in the pixel are illustrated as an example.

The source area SC, the active area AL, and the drain area DR of the transistor 100PC may be formed from the semiconductor pattern SC, AL, DR, and SCL. The source area SC and the drain area DR may extend from the active area AL in opposite directions on the section. In FIG. 8, a portion of the connecting signal line SCL formed from the semiconductor pattern SC, AL, DR, and SCL is illustrated. Although not separately illustrated, the connecting signal line SCL may be connected to the drain area DR of the transistor 100PC, in a plan view.

A first insulating layer 10 may be disposed on the buffer layer BFL. The first insulating layer 10 may commonly overlap the plurality of pixels and may cover the semiconductor pattern SC, AL, DR, and SCL. The first insulating layer 10 may be an inorganic layer and/or an organic layer and may have a single-layer structure or a multi-layer structure. The first insulating layer 10 may include aluminum oxide, titanium oxide, silicon oxide, silicon nitride, silicon oxy nitride, zirconium oxide, and/or hafnium oxide. In this embodiment, the first insulating layer 10 may be a single silicon oxide layer. Not only the first insulating layer 10 but also insulating layers of the circuit layer 120 that will be described below may be inorganic layers and/or organic layers and may have a single-layer structure or a multi-layer structure. The inorganic layers may include at least one of the aforementioned materials, but are not necessarily limited thereto.

A gate GT of the transistor 100PC is disposed on the first insulating layer 10. The gate GT may be a portion of a metal pattern. The gate GT overlaps the active area AL. The gate GT may function as a mask in a process of doping or reducing the semiconductor pattern SC, AL, DR, and SCL.

A second insulating layer 20 may be disposed on the first insulating layer 10 and may cover the gate GT. The second insulating layer 20 may commonly overlap the pixels. The second insulating layer 20 may be an inorganic layer and/or an organic layer and may have a single-layer structure or a multi-layer structure. The second insulating layer 20 may include silicon oxide, silicon nitride, and/or silicon oxy nitride. In this embodiment, the second insulating layer 20 may have a multi-layer structure including a silicon oxide layer and a silicon nitride layer.

A third insulating layer 30 may be disposed on the second insulating layer 20. The third insulating layer 30 may have a single-layer structure or a multi-layer structure. For example, the third insulating layer 30 may have a multi-layer structure including a silicon oxide layer and a silicon nitride layer.

A first connecting electrode CNE1 may be disposed on the third insulating layer 30. The first connecting electrode CNE1 may be connected to the connecting signal line SCL through a contact hole CNT-1 penetrating the first, second, and third insulating layers 10, 20, and 30.

A fourth insulating layer 40 may be disposed on the third insulating layer 30. The fourth insulating layer 40 may be a single silicon oxide layer. A fifth insulating layer 50 may be disposed on the fourth insulating layer 40. The fifth insulating layer 50 may be an organic layer.

A second connecting electrode CNE2 may be disposed on the fifth insulating layer 50. The second connecting electrode CNE2 may be connected to the first connecting electrode CNE1 through a contact hole CNT-2 penetrating the fourth insulating layer 40 and the fifth insulating layer 50.

A sixth insulating layer 60 may be disposed on the fifth insulating layer 50 and may cover the second connecting electrode CNE2. The sixth insulating layer 60 may be an organic layer.

The light emitting element layer 130 may be disposed on the circuit layer 120. The light emitting element layer 130 may include the light emitting element 100PE. For example, the light emitting element layer 130 may include an organic luminescent material, an inorganic luminescent material, an organic-inorganic luminescent material, a quantum dot, a quantum rod, a micro LED, or a nano LED. Hereinafter, it will be exemplified that the light emitting element 100PE is an organic light emitting element. However, the present disclosure is not necessarily particularly limited thereto.

The light emitting element 100PE may include a first electrode AE, an emissive layer EL, and a second electrode CE.

The first electrode AE may be disposed on the sixth insulating layer 60. The first electrode AE may be connected to the second connecting electrode CNE2 through a contact hole CNT-3 penetrating the sixth insulating layer 60.

A pixel defining layer 70 may be disposed on the sixth insulating layer 60 and may cover a portion of the first electrode AE. The pixel defining layer 70 may have an opening 70-OP defined therein. The opening 70-OP of the pixel defining layer 70 exposes at least a portion of the first electrode AE.

The active area DA (refer to FIG. 2) may include an emissive area PXA and a non-emissive area NPXA adjacent to the emissive area PXA. The non-emissive area NPXA may surround the emissive area PXA. In this embodiment, the emissive area PXA is defined to correspond to a partial area of the first electrode AE exposed through the opening 70-OP.

The emissive layer EL may be disposed on the first electrode AE. The emissive layer EL may be disposed within an area corresponding to the opening 70-OP. For example, the emissive layer EL may be separately formed for each of the pixels. When the emissive layer EL is separately formed for each of the pixels, the emissive layers EL may each emit blue light, red light, and/or green light. However, without necessarily being limited thereto, the emissive layer EL may be connected to the pixels and may be commonly included in the pixels. In this case, the emissive layer EL may provide blue light or white light.

The second electrode CE may be disposed on the emissive layer EL. The second electrode CE may have a one-body shape and may be commonly included in the plurality of pixels.

In an embodiment of the present disclosure, a hole control layer may be disposed between the first electrode AE and the emissive layer EL. The hole control layer may be commonly disposed within the emissive area PXA and the non-emissive area NPXA. The hole control layer may include a hole transport layer and may further include a hole injection layer. An electron control layer may be disposed between the emissive layer EL and the second electrode CE. The electron control layer may include an electron transport layer and may further include an electron injection layer. The hole control layer and the electron control layer may be commonly formed in the plurality of pixels using an open mask or an ink-jet process.

The encapsulation layer 140 may be disposed on the light emitting element layer 130. The encapsulation layer 140 may include an inorganic layer, an organic layer, and an inorganic layer that are sequentially stacked one above another. However, layers constituting the encapsulation layer 140 are not necessarily limited thereto. The inorganic layers may protect the light emitting element layer 130 from moisture and oxygen, and the organic layer may protect the light emitting element layer 130 from foreign matter such as dust particles. The inorganic layers may include a silicon nitride layer, a silicon oxy nitride layer, a silicon oxide layer, a titanium oxide layer, or an aluminum oxide layer. The organic layer may include an acrylic organic layer, but is not necessarily limited thereto.

The sensor layer 200 may include a base layer 201, a first conductive layer 202, a sensing insulation layer 203, a second conductive layer 204, and a cover insulating layer 205.

The base layer 201 may be an inorganic layer including silicon nitride, silicon oxy nitride, and/or silicon oxide. Alternatively, the base layer 201 may be an organic layer including an epoxy resin, an acrylic resin, or an imide-based resin. The base layer 201 may have a single-layer structure, or may have a multi-layer structure stacked in the third direction DR3.

Each of the first conductive layer 202 and the second conductive layer 204 may have a single-layer structure, or may have a multi-layer structure stacked in the third direction DR3.

Each of the first conductive layer 202 and the second conductive layer 204 that have a single-layer structure may include a metal layer or a transparent conductive layer. The metal layer may include molybdenum, silver, titanium, copper, aluminum, or an alloy thereof. The transparent conductive layer may include transparent conductive oxide such as indium tin oxide (ITO), indium zinc oxide (IZO), zinc oxide (ZnO), indium zinc tin oxide (IZTO), or the like. In addition, the transparent conductive layer may include a conductive polymer such as poly (3,4-ethylenedioxythiophene) (PEDOT), a metal nano wire, or graphene.

Each of the first conductive layer 202 and the second conductive layer 204 that have a multi-layer structure may include metal layers. The meal layers may have, for example, a three-layer structure of titanium/aluminum/titanium. The conductive layer having the multi-layer structure may include at least one metal layer and at least one transparent conductive layer.

The sensing insulation layer 203 and/or the cover insulating layer 205 may include an inorganic film. The inorganic film may include aluminum oxide, titanium oxide, silicon oxide, silicon nitride, silicon oxy nitride, zirconium oxide, and/or hafnium oxide.

The sensing insulation layer 203 and/or the cover insulating layer 205 may include an organic film. The organic film may include an acrylic resin, a methacrylic resin, a polyisoprene resin, a vinyl resin, an epoxy resin, a urethane-based resin, a celluosic resin, a siloxane-based resin, a polyimide resin, a polyamide resin, or a perylene-based resin.

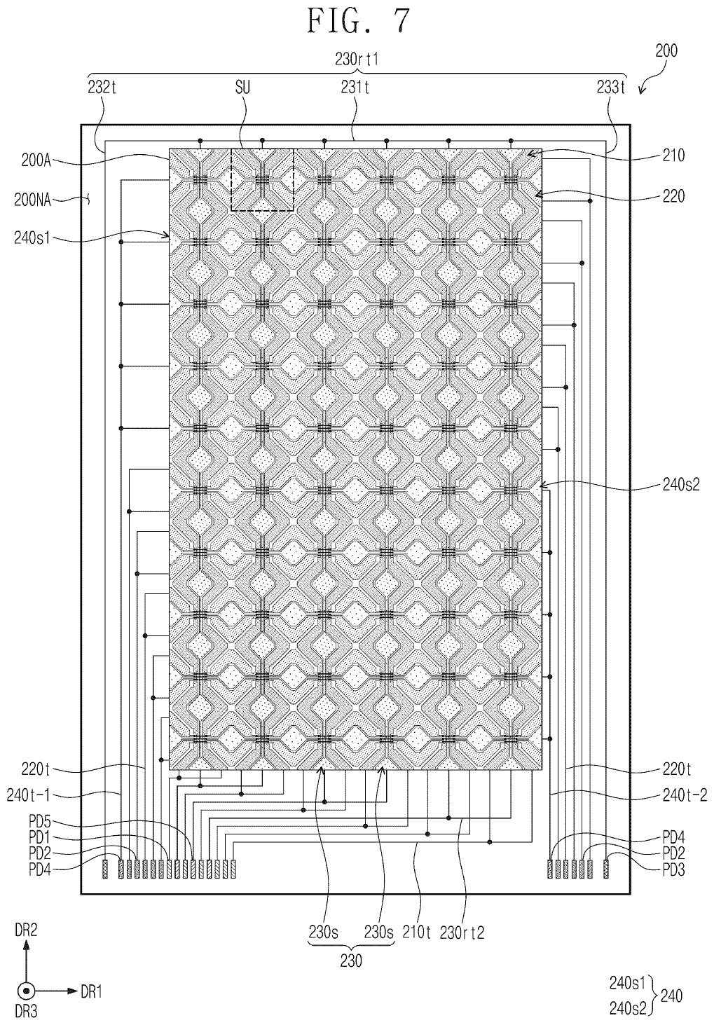

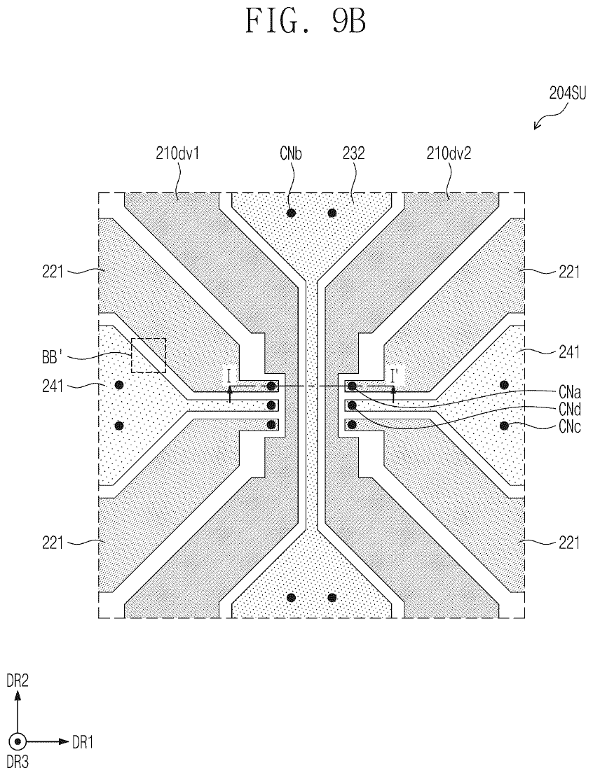

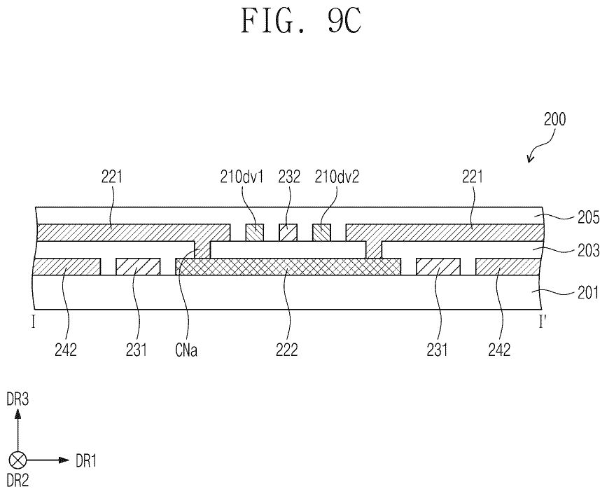

FIG. 7 is a plan view of the sensor layer according to an embodiment of the present disclosure. FIG. 8 is an enlarged plan view illustrating one sensing unit according to an embodiment of the present disclosure. FIG. 9A is a plan view illustrating a first conductive layer of the sensing unit according to an embodiment of the present disclosure. FIG. 9B is a plan view illustrating a second conductive layer of the sensing unit according to an embodiment of the present disclosure. FIG. 9C is a cross-sectional view of the sensor layer taken along line I-I′ illustrated in FIGS. 9A and 9B.

Referring to FIGS. 7 to 9C, an active area 200A and a peripheral area 200NA adjacent to the active area 200A may be defined in the sensor layer 200.

The sensor layer 200 may include a plurality of sensing units SU disposed within the active area 200A. The plurality of sensing units SU may be arranged in the first direction DR1 and the second direction DR2.

The sensor layer 200 may include a plurality of first electrodes 210, a plurality of second electrodes 220, a plurality of third electrodes 230, and a plurality of fourth electrodes 240.

Each of the plurality of first electrodes 210 may cross the plurality of second electrodes 220. Each of the plurality of first electrodes 210 may extend in the second direction DR2. The plurality of first electrodes 210 may be arranged in the first direction DR1 so as to be spaced apart from one another.

Each of the plurality of second electrodes 220 may extend in the first direction DR1. The plurality of second electrodes 220 may be arranged in the second direction DR2 so as to be spaced apart from one another.

A sensing unit SU of the sensor layer 200 may be an area where one first electrode 210 and one second electrode 220 cross each other.

The sensing unit SU may include one first electrode 210 among the plurality of first electrodes 210, one second electrode 220 among the plurality of second electrodes 220, one third electrode 230 among the plurality of third electrodes 230, and one fourth electrode 240 among the plurality of fourth electrodes 240.

Each of the first electrodes 210 may include first divided electrodes 210dv1 and 210dv2. The first divided electrodes 210dv1 and 210dv2 may extend in the second direction DR2 and may be spaced apart from each other in the first direction DR1. The first divided electrodes 210dv1 and 210dv2 may have shapes having line symmetry with respect to a line extending in the second direction DR2, where “line symmetry” is defined as mirror symmetry about the particular line.

Each of the second electrodes 220 may include second divided electrodes 220dv1 and 220dv2. The second divided electrodes 220dv1 and 220dv2 may extend in the first direction DR1 and may be spaced apart from each other in the second direction DR2. The second divided electrodes 220dv1 and 220dv2 may have shapes having line symmetry with respect to a line extending in the first direction DR1.

Each of the second divided electrodes 220dv1 and 220dv2 may include a sensing pattern 221 and a bridge pattern 222. The sensing pattern 221 and the bridge pattern 222 may be disposed on different layers. The sensing pattern 221 and the bridge pattern 222 may be electrically connected with each other through a first contact CNa. For example, the bridge pattern 222 may be included in the first conductive layer 202SU, and the sensing pattern 221 and the first divided electrodes 210dv1 and 210dv2 may be included in the second conductive layer 204SU. The first conductive layer 202SU may be included in the first conductive layer 202 of FIG. 6, and the second conductive layer 204SU may be included in the second conductive layer 204 of FIG. 6.

Each of the third electrodes 230 may extend in the second direction DR2. The third electrodes 230 may be arranged in the first direction DR1 so as to be spaced apart from one another. In an embodiment of the present disclosure, each of the third electrodes 230 may include a plurality of first auxiliary electrodes 230s connected in parallel. The number of first auxiliary electrodes 230s included in each of the third electrodes 230 may be diversely modified. For example, as the number of first auxiliary electrodes 230s included in each of the third electrodes 230 is increased, the resistance of the third electrode 230 may be lowered, and thus power efficiency and sensing sensitivity may be increased. In contrast, as the number of first auxiliary electrodes 230s included in each of the third electrodes 230 is decreased, a loop coil pattern formed using the third electrodes 230 may be implemented in more various forms.

Although FIG. 7 illustrates an example that one third electrode 230 includes two first auxiliary electrodes 230s, the present disclosure is not necessarily particularly limited thereto. The first auxiliary electrodes 230s may be disposed to correspond to the first electrodes 210 in a one-to-one manner. Accordingly, one sensing unit SU may include a portion of one first auxiliary electrode 230s.

A coupling capacitor may be defined between one first electrode 210 and one first auxiliary electrode 230s. In this case, an induced current generated when the pen is sensed may be transferred from the first auxiliary electrode 230s to the first electrode 210 through the coupling capacitor. For example, the first auxiliary electrode 230s may serve to supplement a signal transferred from the first electrode 210 to the sensor driver 200C. Accordingly, the greatest effect may be obtained when the phase of a signal induced in the first auxiliary electrode 230s coincides with the phase of a signal induced in the first electrode 210. Thus, the centers of the first electrodes 210 in the second direction DR2 may overlap the centers of the first auxiliary electrodes 230s in the second direction DR2. In addition, the centers of the first electrodes 210 in the first direction DR1 may overlap the centers of the first auxiliary electrodes 230s in the first direction DR1.

In an embodiment of the present disclosure, since one third electrode 230 includes two first auxiliary electrodes 230s, the one third electrode 230 may correspond to (or, overlap) two first electrodes 210. Accordingly, the number of first electrodes included in the sensor layer 200 may be greater than the number of third electrodes 230. For example, the number of first electrodes 210 may be equal to the product of the number of third electrodes 230 included in the sensor layer 200 and the number of first auxiliary electrodes 230s included in each of the third electrodes 230. In FIG. 9, the number of first electrodes 210 may be six, the number of third electrodes 230 may be three, and the number of first auxiliary electrodes 230s included in each of the third electrodes 230 may be two.

The fourth electrodes 240 may be arranged in the second direction DR2. The fourth electrodes 240 may extend in the first direction DR1. In an embodiment of the present disclosure, each of the fourth electrodes 240 may include second auxiliary electrodes 240s1 or 240s2 connected in parallel. The second auxiliary electrodes 240s1 or 240s2 may be referred to as a second-first auxiliary electrode 240s1 or a second-second auxiliary electrode 240s2.

The routing directions of the second auxiliary electrode 240s1 and the second auxiliary electrode 240s2 may be different from each other. In FIG. 9, two fourth electrodes 240 and five second auxiliary electrodes 240s1 or 240s2 included in each of the fourth electrodes 240 are illustrated as an example.

In this specification, when the routing directions are different from each other, this means that the connection positions of electrodes and trace lines are different from each other. For example, a first connection position of a fourth trace line 240t-1 electrically connected with the second auxiliary electrode 240s1 may be different from a second connection position of a fourth trace line 240t-2 electrically connected with the second auxiliary electrode 240s2. The first connection position may be a left end with respect to the second auxiliary electrodes 240s1, and the second connection position may be a right end with respect to the second auxiliary electrodes 240s2.

In an embodiment of the present disclosure, the sensor layer 200 may include one fourth electrode. In this case, the fourth electrode may include ten second auxiliary electrodes connected in parallel. The number of the second auxiliary electrodes is only described based on the drawing of FIG. 9, and the number of second auxiliary electrodes included in the fourth electrode is not necessarily limited to the above-described example.

FIG. 7 illustrates an example that five second auxiliary electrodes 240s1 are electrically connected together and five second auxiliary electrodes 240s2 are electrically connected together. For example, the ratio between the areas of two fourth electrodes 240 or the ratio between the numbers of second auxiliary electrodes included in the two fourth electrodes 240 may have a ratio of 1:1. However, the present disclosure is not necessarily particularly limited thereto. For example, the number of second auxiliary electrodes 240s1 and the number of second auxiliary electrodes 240s2 may be different from each other.

In an embodiment of the present disclosure, when each of the fourth electrodes 240 includes the second auxiliary electrodes 240s1 or 240s2 connected in parallel, an effect of increasing the area of one fourth electrode may be obtained. In addition, the resistance of each of the fourth electrodes 240 may be lowered, and thus the sensing sensitivity for the second input 3000 (refer to FIG. 5) may be increased.

A coupling capacitor may be defined between one second electrode 220 and one second auxiliary electrode 240s1. In this case, an induced current generated when the pen is sensed may be transferred from the second auxiliary electrode 240s1 to the second electrode 220 through the coupling capacitor. For example, the second auxiliary electrode 240s1 may serve to supplement a signal transferred from the second electrode 220 to the sensor driver 200C. Accordingly, the greatest effect may be obtained when the phase of a signal induced in the second auxiliary electrode 240s1 coincides with the phase of a signal induced in the second electrode 220. Accordingly, the center of each of the second electrodes 220 in the first direction DR1 may overlap the center of the second auxiliary electrode 240s1 in the first direction DR1. In addition, the center of each of the second electrodes 220 in the second direction DR2 may overlap the center of the second auxiliary electrode 240s1 in the second direction DR2.

Each of the first auxiliary electrodes 230s included in the third electrode 230 may include a third-first pattern 231 and a third-second pattern 232. The third-first pattern 231 and the third-second pattern 232 may be disposed on different layers. The third-first pattern 231 and the third-second pattern 232 may be electrically connected with each other through a second contact CNb. The third-first pattern 231 may be included in the first conductive layer 202SU, and the third-second pattern 232 may be included in the second conductive layer 204SU.

In an embodiment of the present disclosure, a portion of the third-first pattern 231 may overlap a portion of each of the first divided electrodes 210dv1 and 210dv2. Accordingly, coupling capacitance may be provided (or, formed) between the first electrode 210 and the third electrode 230.

Each of the second auxiliary electrodes 240s1 or 240s2 included in the fourth electrode 240 may include a fourth-first pattern 241, a fourth-second pattern 242, and a fourth-third pattern 243. The fourth-second pattern 242 and the fourth-third pattern 243 may be disposed on the same layer, and the fourth-first pattern 241 may be disposed on a layer different from the layer on which the fourth-second pattern 242 and the fourth-third pattern 243 are disposed. The fourth-first pattern 241 and the fourth-second pattern 242 may be electrically connected with each other through a third contact CNc, and the fourth-first pattern 241 and the fourth-third pattern 243 may be electrically connected with each other through a fourth contact CNd. The fourth-second pattern 242 and the fourth-third pattern 243 may be included in the first conductive layer 202SU, and the fourth-first pattern 241 may be included in the second conductive layer 204SU.

In an embodiment of the present disclosure, a portion of the fourth-second pattern 242 may overlap the sensing pattern 221 of each of the second divided electrodes 220dv1 and 220dv2. Accordingly, a coupling capacitor may be defined (or, provided or formed) between the second electrode 220 and the fourth electrode 240.

In an embodiment of the present disclosure, the first conductive layer 202SU may further include dummy patterns DMP. Each of the dummy patterns DMP may be electrically floated or electrically grounded. In an embodiment of the present disclosure, the dummy patterns DMP may be omitted.

The sensor layer 200 may further include a plurality of first trace lines 210t disposed within the peripheral area 200NA, a plurality of first pads PD1 connected to the first trace lines 210t in a one-to-one correspondence, a plurality of second trace lines 220t, and a plurality of second pads PD2 connected to the second trace lines 220t in a one-to-one correspondence.

The first trace lines 210t may be electrically connected to the first electrodes 210 in a one-to-one correspondence. Two first divided electrodes 210dv1 and 210dv2 included in one first electrode 210 may be connected to one first trace line among the first trace lines 210t. Each of the first trace lines 210t may include a plurality of branch portions for connection to two first divided electrodes 210dv1 and 210dv2. In an embodiment of the present disclosure, the two first divided electrodes 210dv1 and 210dv2 may be connected with each other in the active area 200A.

The second trace lines 220t may be electrically connected to the second electrodes 220 in a one-to-one correspondence. Two second divided electrodes 220dv1 and 220dv2 included in one second electrode 220 may be connected to one second trace line among the second trace lines 220t. Each of the second trace lines 220t may include a plurality of branch portions for connection to two second divided electrodes 220dv1 and 220dv2. In an embodiment of the present disclosure, the two second divided electrodes 210dv1 and 210dv2 may be connected with each other in the active area 200A.

The sensor layer 200 may further include a third trace line 230rt1 disposed within the peripheral area 200NA, a plurality of third pads PD3 connected to one end and an opposite end of the third trace line 230rt1, the fourth trace lines 240t-1 and 240t-2, fourth pads PD4 connected to the fourth trace lines 240t-1 and 240t-2 in a one-to-one correspondence, fifth trace lines 230rt2, and fifth pads PD5 connected to the fifth trace lines 230rt2 in a one-to-one correspondence.

The third trace line 230rt1 may be electrically connected with at least one first auxiliary electrode 230s among the first auxiliary electrodes 230s. In an embodiment of the present disclosure, the third trace line 230rt1 may be electrically connected with all of the first auxiliary electrodes 230s. For example, the third trace line 230rt1 may be electrically connected to all of the third electrodes 230. The third trace line 230rt1 may include a first line portion 231t that extends in the first direction DR1 and that is electrically connected to the third electrodes 230, a second line portion 232t extending from a first end of the first line portion 231t in the second direction DR2, and a third line portion 233t extending from a second end of the first line portion 231t in the second direction DR2.

In an embodiment of the present disclosure, each of the resistance of the second line portion 232t and the resistance of the third line portion 233t may be substantially the same as the resistance of one third electrode among the third electrodes 230. Accordingly, the second line portion 232t and the third line portion 233t may serve as the third electrodes 230, and the same effect as disposing the third electrodes 230 in the peripheral area 200NA may be obtained. For example, one of the second line portion 232t and the third line portion 233t and one of the third electrodes 230 may form a coil. Accordingly, the pen located in an area adjacent to the peripheral area 200NA may also be sufficiently charged by a loop including the second line portion 232t or the third line portion 233t.

In an embodiment of the present disclosure, to adjust the resistance of the second line portion 232t and the resistance of the third line portion 233t, the widths of the second line portion 232t and the third line portion 233t in the first direction DR1 may be adjusted. However, the first to third line portions 231t, 232t, and 233t may have substantially the same width.

The fifth trace lines 230rt2 may be connected to the third electrodes 230 in a one-to-one correspondence. For example, the number of fifth trace lines 230rt2 may correspond to the number of third electrodes 230. In FIG. 9, three fifth trace lines 230rt2 are illustrated as an example.

In an embodiment of the present disclosure, the fifth trace lines 230t2 and the fifth pads PD5 may be omitted, and a charging driving mode for charging the pen may be omitted. In this case, the sensor layer 200 may sense an input by an active pen capable of emitting a magnetic field even though a magnetic field is not provided from the sensor layer 200.

The fourth trace lines 240t-1 and 240t-2 may be spaced apart from each other with the active area 200A therebetween. The fourth trace line 240t-1 may be electrically connected to at least one second auxiliary electrode 240s1 among the second auxiliary electrodes 240s1. For example, one end of each of the second auxiliary electrodes 240s1 may be connected to the fourth trace line 240t-1. The fourth trace line 240t-2 may be electrically connected to at least one second auxiliary electrode 240s2 among the second auxiliary electrodes 240s2. For example, one end of each of the second auxiliary electrodes 240s2 may be connected to the fourth trace line 240t-2.

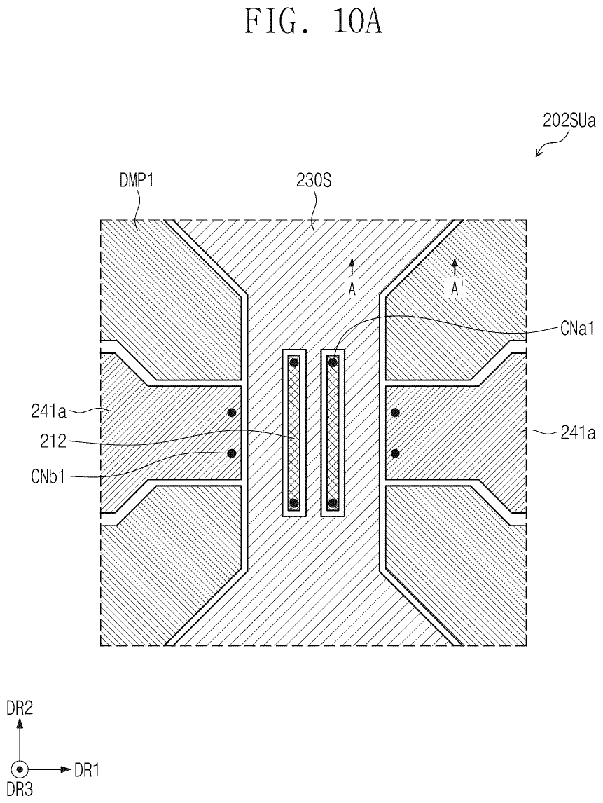

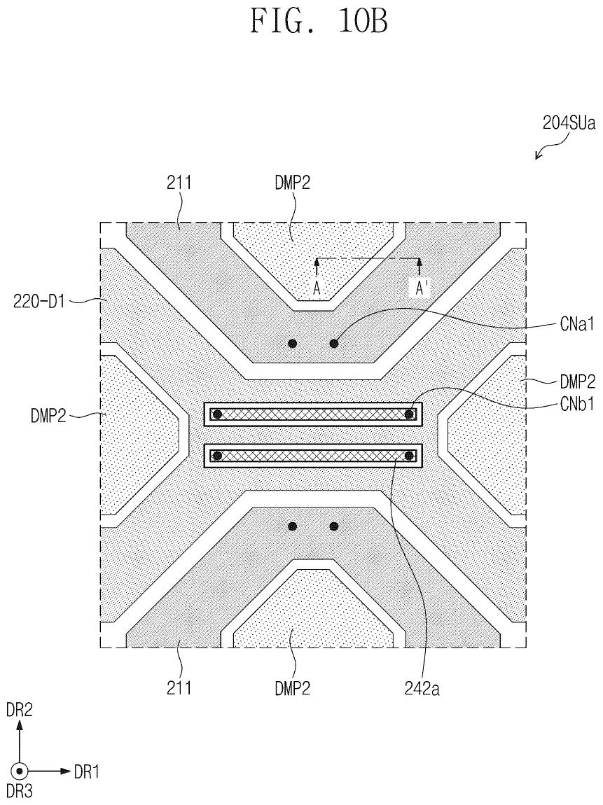

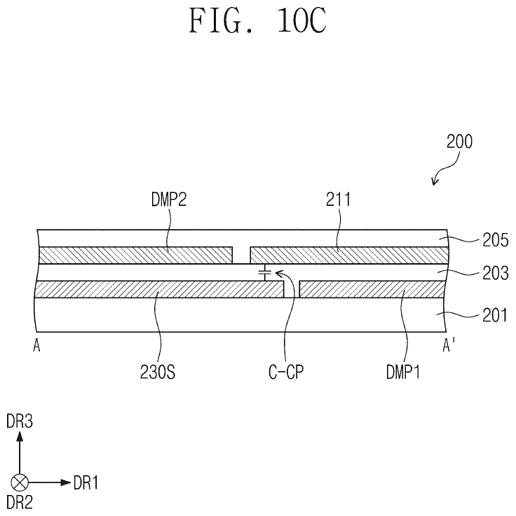

FIG. 10A is a plan view illustrating a first conductive layer of a sensing unit according to an embodiment of the present disclosure. FIG. 10B is a plan view illustrating a second conductive layer of the sensing unit according to an embodiment of the present disclosure. FIG. 10C is a cross-sectional view of the sensor layer taken along line A-A′ illustrated in FIGS. 10A and 10B according to an embodiment of the present disclosure.

Referring to FIGS. 8, 10A, 10B, and 10C, each of the plurality of first electrodes 210 may include a plurality of first sensing patterns 211 and a plurality of first bridge patterns 212. The first sensing patterns 211 may be spaced apart from one another in the second direction DR2, and the first bridge patterns 212 may extend in the second direction DR2 and may be electrically connected to the first sensing patterns 211 through a first contact CNa1. Although FIGS. 10A and 10B illustrate an example that two first sensing patterns 211 adjacent to each other are electrically connected with each other by two first bridge patterns 212, the present disclosure is not necessarily particularly limited thereto. For example, two first sensing patterns 211 adjacent to each other may be electrically connected with each other by one first bridge pattern 212, or may be electrically connected with each other by three or more first bridge patterns 212.

In FIG. 10B, the first one of a first divided electrode 220-D1 and a second divided electrode 220-D2 is illustrated as an example. The first sensing patterns 211 adjacent to each other in the second direction DR2 may be spaced apart from each other with the first divided electrode 220-D1 therebetween. In an embodiment of the present disclosure, the first sensing patterns 211, the first divided electrode 220-D1, and the second divided electrode 220-D2 may be included in the second conductive layer 204SUa, and the first bridge patterns 212 may be included in the first conductive layer 202SUa. The first bridge patterns 212 may be insulated from the first divided electrode 220-D1 or the second divided electrode 220-D2 that overlaps the first bridge patterns 212 and may cross the first divided electrode 220-D1 or the second divided electrode 220-D2.

Each of the first auxiliary electrodes 230S included in the plurality of third electrodes 230 may extend in the second direction DR2. The first auxiliary electrodes 230S may be included in the first conductive layer 202SUa. One or more holes may be defined in each of the first auxiliary electrodes 230S. One first bridge pattern 212 may be disposed within one hole. Accordingly, the first bridge pattern 212 may be electrically insulated from the first auxiliary electrodes 230S.

Each of the second auxiliary electrodes 240S included in the plurality of fourth electrodes 240 may include a plurality of second sensing patterns 241a and a plurality of second bridge patterns 242a. The second sensing patterns 241a may be spaced apart from one another in the first direction DR1, and the second bridge patterns 242a may extend in the first direction DR1 and may be electrically connected to the second sensing patterns 241a through a second contact CNb1.

Although FIGS. 10A and 10B illustrate an example that two second sensing patterns 241a adjacent to each other are electrically connected with each other by two second bridge patterns 242a, the present disclosure is not necessarily particularly limited thereto. For example, two second sensing patterns 241a adjacent to each other may be electrically connected with each other by one second bridge pattern 242a, or may be electrically connected with each other by three or more second bridge patterns 242a.

In an embodiment of the present disclosure, the second sensing patterns 241a and the first auxiliary electrodes 230S may be included in the first conductive layer 202SUa, and the second bridge patterns 242a may be included in the second conductive layer 204SUa. The second bridge patterns 242a may be insulated from the first auxiliary electrodes 230S overlapping the second bridge patterns 242a and may cross the first auxiliary electrodes 230S.

Referring to FIGS. 10A and 10B, in the second conductive layer 204SUa in one sensing unit SU, the area occupied by components included in the plurality of first electrodes 210 and the plurality of second electrodes 220 may be larger than the area occupied by components included in the plurality of third electrodes 230 and the plurality of fourth electrodes 240. A change in capacitance by the first input 2000 (refer to FIG. 5) may be increased as the distance is decreased. Accordingly, a component for sensing the first input 2000 (refer to FIG. 5) may be disposed within a relatively large area in a layer adjacent to the surface of the electronic device 1000 (refer to FIG. 1). Thus, touch performance may be increased.

In an embodiment of the present disclosure, the first conductive layer 202SUa may further include first dummy patterns DMP1, and the second conductive layer 204SUa may further include second dummy patterns DMP2. The first dummy patterns DMP1 and the second dummy patterns DMP2 may be floated, or may be electrically floated. The first dummy patterns DMP1 and the second dummy patterns DMP2 may each be divided into a plurality of conductive patterns. For example, one first dummy pattern DMP1 may include a plurality of floating dummy patterns that are separated or electrically isolated from one another.

Referring to FIG. 10C, the area of the first auxiliary electrode 230S and the area of the first sensing pattern 211 may be adjusted. For example, the position of the boundary between the first auxiliary electrode 230S and the first dummy patterns DMP1 and the position of the boundary between the first sensing pattern 211 and the second dummy patterns DMP2 may be adjusted. In this case, the area of the overlapping area between the first auxiliary electrode 230S and the first sensing pattern 211 may be adjusted, and the magnitude of the capacitance of a coupling capacitor C-CP between the first auxiliary electrode 230S and the first sensing pattern 211 may be adjusted accordingly.

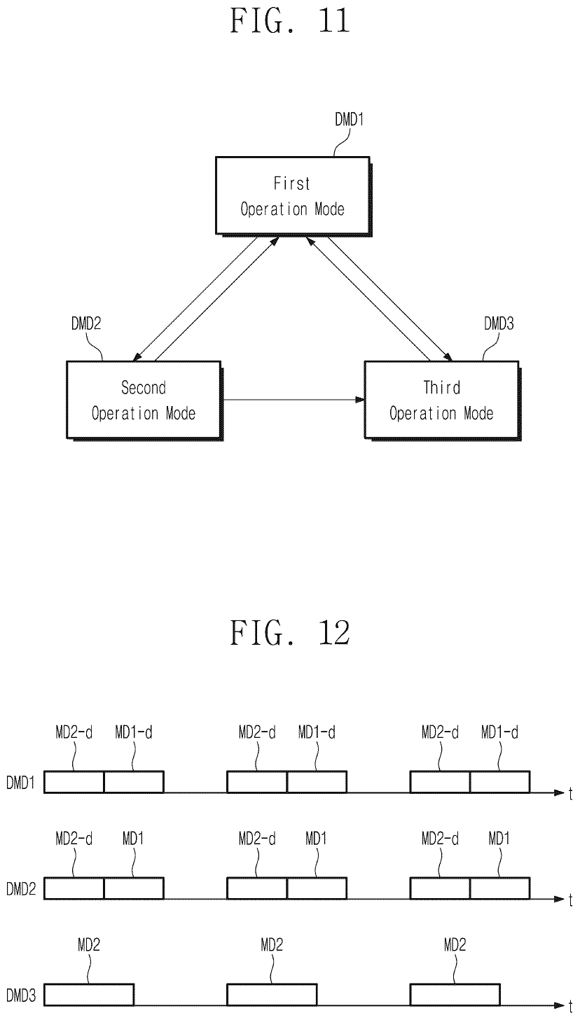

FIG. 11 is a view illustrating an operation of the sensor driver according to an embodiment of the present disclosure.

Referring to FIGS. 5 and 11, the sensor driver 200C may be selectively driven in one of a first operation mode DMD1, a second operation mode DMD2, and a third operation mode DMD3.

The first operation mode DMD1 may be referred to as a touch and pen standby mode, the second operation mode DMD2 may be referred to as a touch activation and pen standby mode, and the third operation mode DMD3 may be referred to as a pen activation mode. The first operation mode DMD1 may be a mode in which the sensor driver 200C waits for the first input 2000 and the second input 3000. The second operation mode DMD2 may be a mode in which the sensor driver 200C senses the first input 2000 and waits for the second input 3000. The third operation mode DMD3 may be a mode in which the sensor driver 200C senses the second input 3000.

In an embodiment of the present disclosure, the sensor driver 200C may first be driven in the first operation mode DMD1. When the first input 2000 is sensed in the first operation mode DMD1, the sensor driver 200C may be switched (or, changed) to the second operation mode DMD2. Alternatively, when the second input 3000 is sensed in the first operation mode DMD1, the sensor driver 200C may be switched (or, changed) to the third operation mode DMD3.

In an embodiment of the present disclosure, when the second input 3000 is sensed in the second operation mode DMD2, the sensor driver 200C may be switched to the third operation mode DMD3. When the first input 2000 is released (or, not sensed) in the second operation mode DMD2, the sensor driver 200C may be switched to the first operation mode DMD1. When the second input 3000 is released (or, not sensed) in the third operation mode DMD3, the sensor driver 200C may be switched to the first operation mode DMD1.

FIG. 12 is a view illustrating an operation of the sensor driver according to an embodiment of the present disclosure.

Referring to FIGS. 5, 7, 11, and 12, operations in the first to third operation modes DMD1, DMD2, and DMD3 are illustrated in order of time (t).

In the first operation mode DMD1, the sensor driver 200C may be repeatedly driven in a second mode MD2-d and a first mode MD1-d. During the second mode MD2-d, the sensor layer 200 may be scan-driven to detect the second input 3000. During the first mode MD1-d, the sensor layer 200 may be scan-driven to detect the first input 2000. Although FIG. 12 illustrates an example that the sensor driver 200C operates in the first mode MD1-d continuously after the second mode MD2-d, the order is not necessarily limited thereto.

In the second operation mode DMD2, the sensor driver 200C may be repeatedly driven in a second mode MD2-d and a first mode MD1. During the second mode MD2-d, the sensor layer 200 may be scan-driven to detect the second input 3000. During the first mode MD1, the sensor layer 200 may be scan-driven to detect the coordinates by the first input 2000.

In the third operation mode DMD3, the sensor driver 200C may be driven in a second mode MD2. During the second mode MD2, the sensor layer 200 may be scan-driven to detect the coordinates by the second input 3000. In the third operation mode DMD3, the sensor driver 200C might not operate in the first mode MD1-D or MDI until the second input 3000 is released (or, not sensed).

In the first mode MD1-d and the first mode MD1, the third electrodes 230 and the fourth electrodes 240 may all be grounded. Accordingly, touch noise may be prevented from being introduced through the third electrodes 230 and the fourth electrodes 240.

In the second mode MD2-d and the second mode MD2, first ends of the third electrodes 230 and the fourth electrodes 240 may all be floated. In addition, in the second mode MD2-d and the second mode MD2, second ends of the third electrodes 230 and the fourth electrodes 240 may all be grounded or floated. Accordingly, compensation of a sensing signal may be maximized by the coupling between the first electrodes 210 and the third electrodes 230 and the coupling between the second electrodes 220 and the fourth electrodes 240.

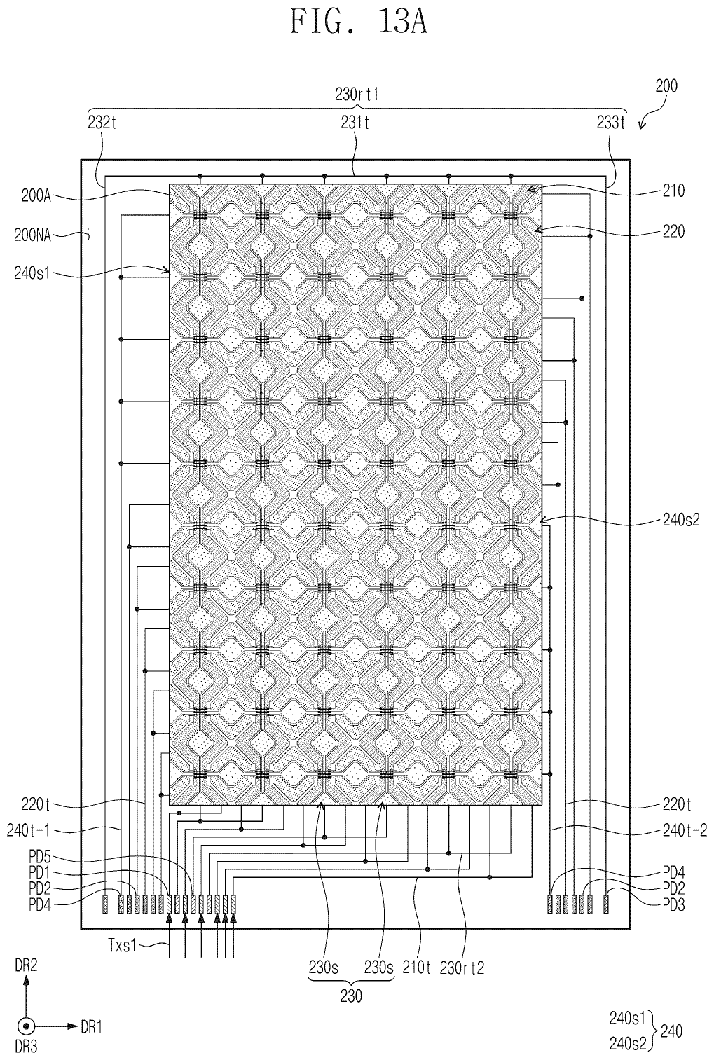

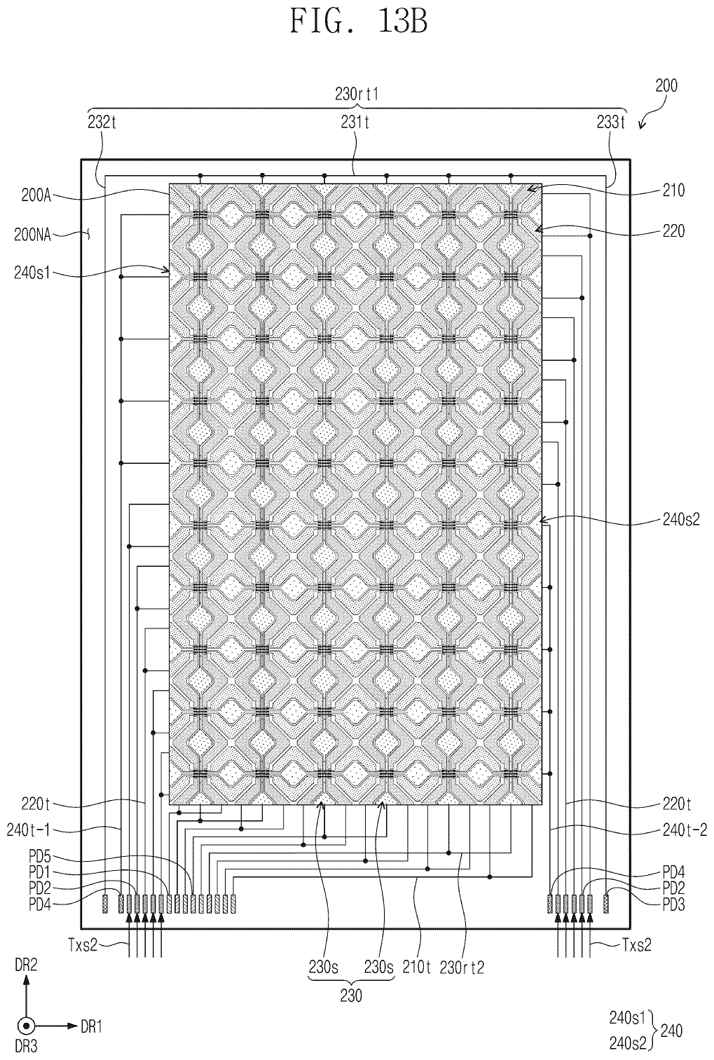

FIGS. 13A and 13B are views illustrating the first mode according to an embodiment of the present disclosure.

Referring to FIGS. 12, 13A, and 13B, the first mode MD1-d and the first mode MD1 may include a self-capacitance detection mode. The self-capacitance detection mode may include a first sub-section and a second sub-section. FIG. 13A is a view illustrating an operation in the first sub-section, and FIG. 13B is a view illustrating an operation in the second sub-section.

In the self-capacitance detection mode, the sensor driver 200C may calculate input coordinates by outputting driving signals Txs1 and Txs2 to the first electrodes 210 and the second electrodes 220 and sensing a change in the capacitance of each of the first electrodes 210 and the second electrodes 220. Referring to FIG. 13A, in the first sub-section, the sensor driver 200C may output the driving signal Txs1 to the first trace lines 210t. Referring to FIG. 13B, in the second sub-section, the sensor driver 200C may output the driving signal Txs2 to the second trace lines 220t.

The third electrodes 230 are electrically connected with the third trace line 230rt1 and the fifth trace lines 230rt2, and the fourth electrodes 240 are electrically connected with the fourth trace lines 240t-1 and 240t-2. In the self-capacitance detection mode, the third electrodes 230 and the fourth electrodes 240 may all be grounded. Accordingly, noise might not be introduced through the third electrodes 230 and the fourth electrodes 240.

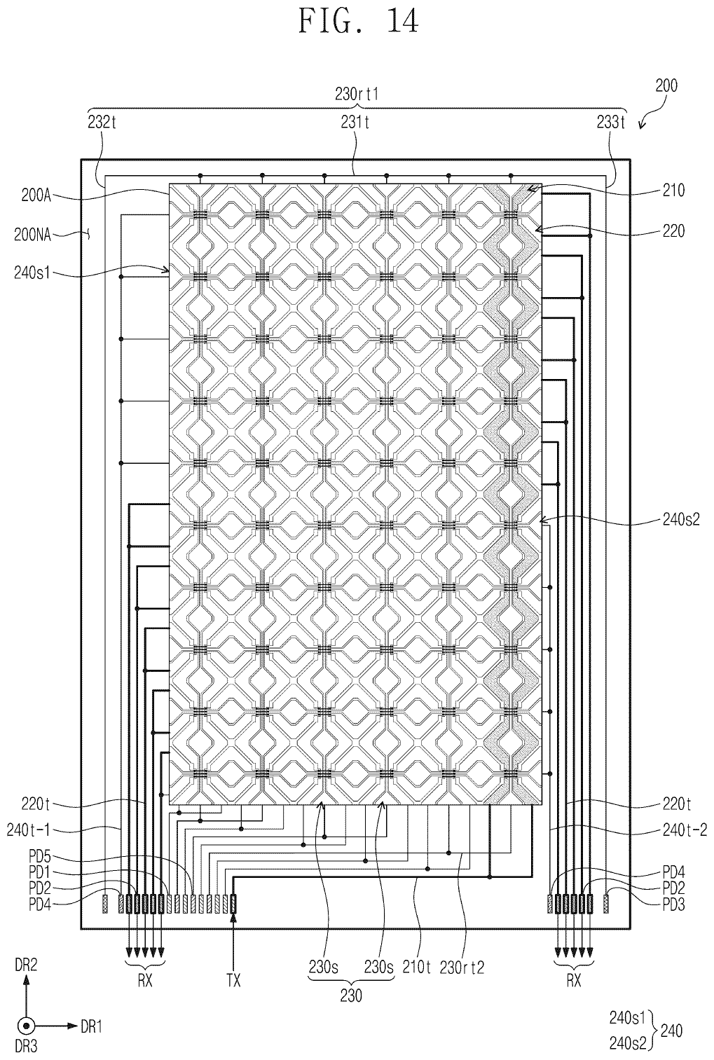

FIG. 14 is a view illustrating the first mode according to an embodiment of the present disclosure.

Referring to FIGS. 5, 12, and 14, the first mode MD1-d and the first mode MD1 may further include a mutual-capacitance detection mode. FIG. 14 is a view illustrating the mutual-capacitance detection mode in the first mode MD1-d and the first mode MD1.

In the mutual-capacitance detection mode, the sensor driver 200C may sequentially provide a transmission signal Tx to the first electrodes 210 and may detect the coordinates for the first input 2000 using a reception signal Rx detected through the second electrodes 220. For example, the sensor driver 200C may sense a change in the mutual capacitance between the first electrodes 210 and the second electrodes 220 and may calculate input coordinates.

FIG. 14 illustrates an example that the transmission signal TX is provided to one first electrode 210 and the reception signal RX is output from the second electrodes 220. In FIG. 14, to clarify the expression of the signals, hatching is drawn on only one first electrode 210 to which the transmission signal TX is provided. The sensor driver 200C may sense a change in the capacitance between the first electrodes 210 and the second electrodes 220 and may detect the input coordinates for the first input 2000.

In the mutual-capacitance detection mode, the third electrodes 230 and the fourth electrodes 240 may all be grounded. Accordingly, noise might not be introduced through the third electrodes 230 and the fourth electrodes 240.

In each of the first mode MD1-d and the first mode MD1, the sensor layer 200 may alternately repeat the operations described with reference to FIGS. 13A, 13B, and 14. However, this is illustrative, and the present disclosure is not necessarily particularly limited thereto. For example, in each of the first mode MD1-d and the first mode MD1, the sensor layer 200 may repeat only the operation described with reference to FIG. 14. Alternatively, in the first mode MD1-d, the sensor layer 200 may repeat only at least one of the operations described with reference to FIGS. 13A, 13B, and 14, and in the first mode MD1, the sensor layer 200 may alternately repeat the operations described with reference to FIGS. 13A, 13B, and 14.

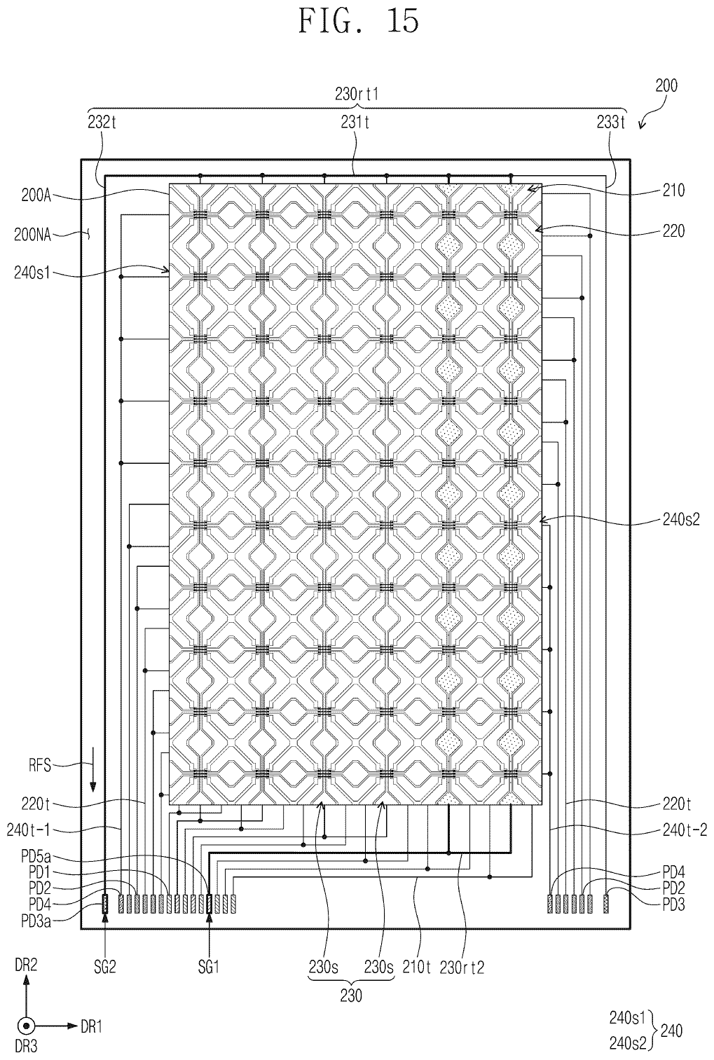

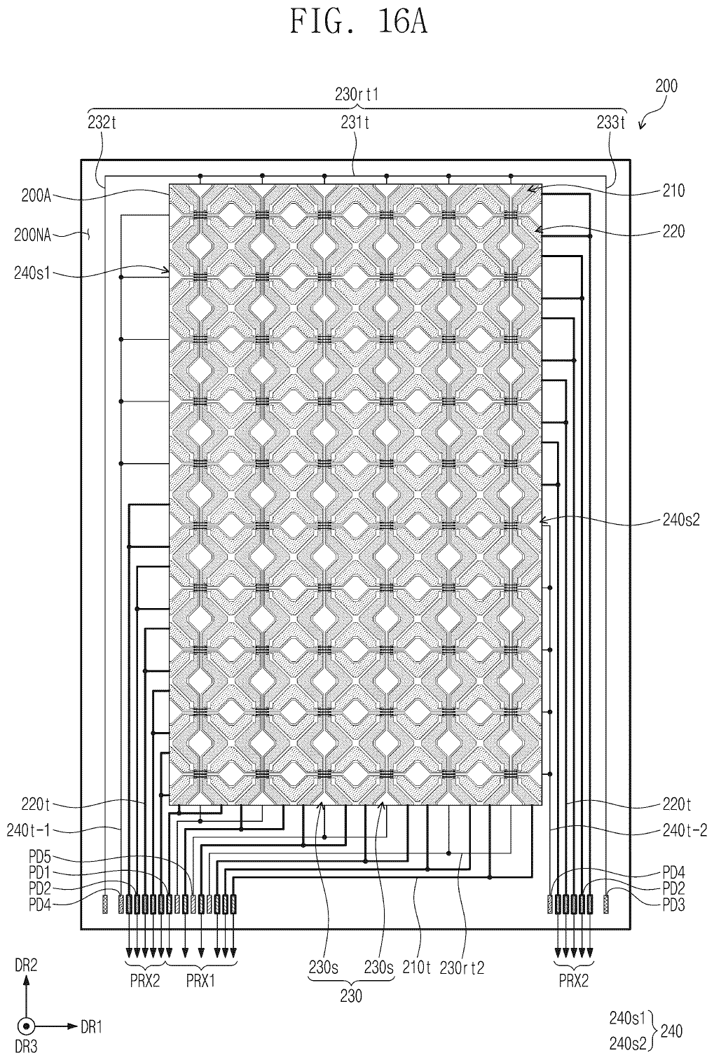

FIG. 15 is a view illustrating the second mode according to an embodiment of the present disclosure.

Referring to FIGS. 5, 12, and 15, the second mode MD2 may include a charging driving mode and a pen sensing driving mode.

In the charging driving mode, the sensor driver 200C may apply a first charging signal SG1 to at least one pad among the third pads PD3 and the fifth pads PD5 and may apply a second charging signal SG2 to at least one other pad. The second charging signal SG2 may be an inverse signal of the first charging signal SG1. For example, the first charging signal SG1 may be a sinusoidal signal or a square-wave signal.

Although FIG. 15 illustrates an example that the first charging signal SG1 is applied to one pad and the second charging signal SG2 is applied to another pad, the present disclosure is not necessarily limited thereto. For example, the first charging signal SG1 may be applied to two or more pads, and the second charging signal SG2 may be applied to two or more other pads.

Since the first charging signal SG1 and the second charging signal SG2 are applied to at least two pads, a current RFS may have a current path to flow through at least one pad to at least one other pad. Furthermore, since the first charging signal SG1 and the second charging signal SG2 are sinusoidal signals having an inverse phase relationship, the direction of the current RFS may be periodically varied.

The first charging signal SG1 and the second charging signal SG2 may have an inverse phase relationship. Accordingly, noise caused in the display layer 100 by the first charging signal SG1 may cancel out noise caused by the second charging signal SG2. Thus, a flicker phenomenon might not occur in the display layer 100, and the display quality of the display layer 100 may be increased.

FIG. 15 illustrates an example that the second charging signal SG2 is provided to one third pad PD3a connected with one third trace line 230rt1 and the first charging signal SG1 is provided to one fifth pad PD5a connected with the third electrode 230. The current RFS may flow along a current path defined by the fifth pad PD5a, the fifth trace line 230t2 connected to the fifth pad PD5a, the third electrode 230, a portion of the third trace line 230t1 connected to the third pad PD3a, and the third pad PD3a. The current path may have a coil shape. Accordingly, in the charging driving mode of the second mode, the resonance circuit of the pen PN may be charged by the current path. In this case, the plurality of third electrodes 230 may be referred to as a plurality of channels.

According to the present disclosure, a current path having a loop coil pattern may be implemented by components included in the sensor layer 200. Accordingly, the electronic device 1000 may charge the pen PN using the sensor layer 200. Thus, a component having a coil for charging the pen PN does not need to be separately added so that an increase in the thickness and weight of the electronic device 1000 and a decrease in the flexibility of the electronic device 1000 might not occur.

In the charging driving mode, the first electrodes 210, the second electrodes 220, and the fourth electrodes 240 may be grounded or electrically floated, or may receive a constant voltage. In particular, the first electrodes 210, the second electrodes 220, and the fourth electrodes 240 may be floated. In this case, the current RFS might not flow to the first electrodes 210, the second electrodes 220, and the fourth electrodes 240.

The charging driving mode may include a searching charging driving mode and a tracking charging driving mode.

Since the position of the pen PN is not sensed in the searching charging driving mode, the first charging signal SG1 or the second charging signal SG2 may be sequentially provided to all channels included in the sensor layer 200. For example, the first charging signal SG1 and the second charging signal SG2 may be sequentially scanned in the first direction DR1. For example, in the searching charging driving mode, the entire active area 200A of the sensor layer 200 may be scanned.

When the pen PN is sensed in the searching charging driving mode, the sensor layer 200 may be driven in the tracking charging driving mode. For example, in the tracking charging driving mode, the sensor driver 200C may sequentially output the first charging signal SG1 and the second charging signal SG2 to an area overlapping the point where the pen PN is sensed, rather than the entire sensor layer 200.

Accordingly, after the position of the pen PN is sensed, channels that are driven for charging may be limited in correspondence to the position of the pen PN in the previous frame. Thus, channels overlapping an area where the pen is not located might not be driven for charging so that the efficiency of charging driving may be increased.

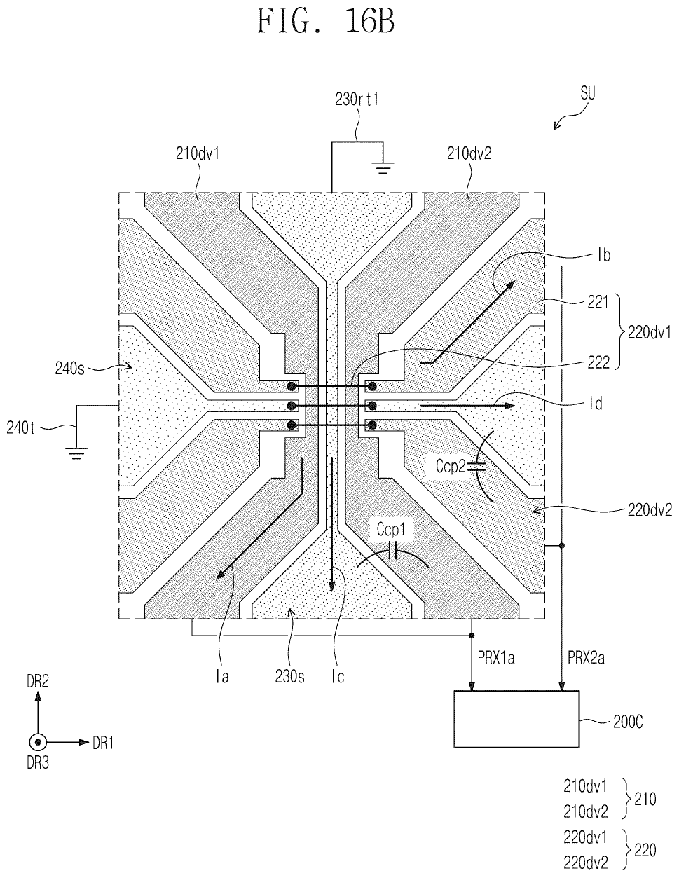

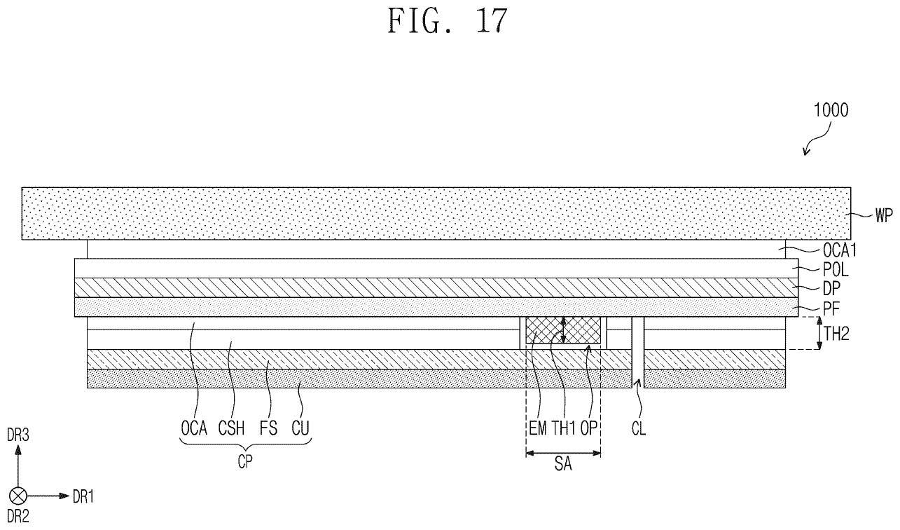

FIG. 16A is a view illustrating the second mode according to an embodiment of the present disclosure, and FIG. 16B is a view illustrating the second mode based on sensing units according to an embodiment of the present disclosure.

Referring to FIGS. 5, 16A, and 16B, in the second mode, the charging driving mode and the pen sensing driving mode may be alternately repeated. In FIG. 16B, one sensing unit SU through which first to fourth induced currents Ia, Ib, Ic, and Id generated by the pen PN flow is illustrated.

The RLC resonance circuit of the pen PN may emit a magnetic field having a resonant frequency while discharging charged charges. Due to the magnetic field provided by the pen PN, the first induced current la may be generated in the first electrode 210, and the second induced current Ib may be generated in the second electrode 230. In addition, the third induced current Ic may be generated in the first auxiliary electrode 230s of the third electrode 230, and the fourth induced current Id may be generated in the second auxiliary electrode 240s of the fourth electrode 240.

A first coupling capacitor Ccp1 may be formed between the first auxiliary electrode 230s and the first electrode 210, and a second coupling capacitor Ccp2 may be formed between the second auxiliary electrode 240s and the second electrode 220. The third induced current Ic may be transferred to the first electrode 210 through the first coupling capacitor Ccp1, and the fourth induced current Id may be transferred to the second electrode 220 through the second coupling capacitor Ccp2. In this case, the plurality of first electrodes 210 and the plurality of second electrodes 220 may each be referred to as a channel.

The sensor driver 200c may receive a first detection signal PRX1a based on the first induced current Ia and the third induced current Ic from the first electrode 210 and may receive a second detection signal PRX2a based on the second induced current Ib and the fourth induced current Id from the second electrode 220. For example, the sensor driver 200C may receive the first detection signal PRX1a from the plurality of first electrodes 210 and may receive the second detection signal PRX2a from the plurality of second electrodes 220. The sensor driver 200C may detect the coordinates of the pen PN, based on the first detection signal PRX1a and/or the second detection signal PRX2a.

The sensor driver 200C may receive the first detection signal PRX1a from the first electrodes 210 and may receive the second detection signal PRX2a from the second electrodes 220. In this case, the first ends of the third electrodes 230 and the fourth electrodes 240 may all be floated. Accordingly, compensation of a sensing signal may be maximized by the coupling between the first electrodes 210 and the third electrodes 230 and the coupling between the second electrodes 220 and the fourth electrodes 240. In addition, the second ends of the third electrodes 230 and the fourth electrodes 240 may be grounded or floated. Accordingly, the third induced current Ic and the fourth induced current Id may be sufficiently transferred to the first electrodes 210 and the second electrodes 220 by the coupling between the first electrodes 210 and the third electrodes 230 and the coupling between the second electrodes 220 and the fourth electrodes 240.

In an embodiment of the present disclosure, the routing directions of an electrode and an auxiliary electrode of the sensor layer 200 that overlap each other may be different from each other. For example, the routing direction of the first electrode 210 and the routing direction of the first auxiliary electrode 230s may be different from each other. In addition, the routing direction of the second electrode 220 and the routing direction of the second auxiliary electrode 240s may be different from each other. For example, in FIG. 16B, the first electrode 210 and the first trace line 210t may be connected on the lower side of the sensing unit SU, and the first auxiliary electrode 230s and the third trace line 230rt1 may be connected on the upper side of the sensing unit SU. The second electrode 220 and the second trace line 2204 may be connected on the left side of the sensing unit SU, and the second auxiliary electrode 240s and the fourth trace line 240t may be connected on the right side of the sensing unit SU.

FIG. 17 is a cross-sectional view of the electronic device according to an embodiment of the present disclosure. In describing FIG. 17, the components described with reference to FIG. 2 will be assigned with the identical reference numerals, and to the extent that an element is not described in detail with respect to this figure, it may be understood that the element is at least similar to a corresponding element that has been described elsewhere within the present disclosure.

Referring to FIG. 17, the electronic device 1000 may include the display panel DP, upper functional layers, and lower functional layers. The upper functional layers may include the window WP, the first adhesive layer OCA1, and the anti-reflective layer POL, and the lower functional layers may include the protective layer PF, the cover panel CP, and an electronic module EM. Components included in the upper functional layers and the lower functional layers are not necessarily limited to the aforementioned components. At least some of the aforementioned components may be omitted, and other components may be added.

The anti-reflective layer POL may decrease the reflectance of external light incident from outside the electronic device 1000. The anti-reflective layer POL may include a stretchable synthetic resin film. For example, the anti-reflective layer POL may be provided by dyeing a polyvinyl alcohol (PVA) film with an iodine compound. However, this is illustrative, and the material of the anti-reflective layer POL is not necessarily limited to the example.

In an embodiment of the present disclosure, the anti-reflective layer POL may be omitted. Alternatively, the anti-reflective layer POL may be embedded in the display panel DP. In this case, the anti-reflective layer POL may include a barrier wall layer that blocks light and a plurality of color filters, or may include an optical layer that prevents reflection and a barrier wall layer that blocks light.

The embo sheet may include an embo pattern to prevent a phenomenon in which bubbles are generated when the cushion layer CSH is attached with the protective layer PF. The cushion sheet may protect the display panel DP from impact transmitted from below. The impact resistance of the electronic device 1000 may be increased by the cushion layer CSH.

An opening OP may be defined in the first adhesive layer OCA and the cushion layer CSH. The electronic module EM may be disposed within the opening OP. The electronic module EM may include the fingerprint sensor 1610 (refer to FIG. 1). However, this is illustrative, and the electronic module EM according to an embodiment of the present disclosure may include the sound output module 1630 (refer to FIG. 1). In this case, the sound output module 1630 (refer to FIG. 1) may include a speaker of a piezoelectric type. Alternatively, the electronic module EM may include a photo sensor.

The magnetic layer FS and the conductive layer CU may be disposed under the electronic module EM. The magnetic layer FS and the conductive layer CU may cover the electronic module EM, in a plan view.

When a fingerprint sensor makes contact with a magnetic layer unlike in the present disclosure, the reliability of the fingerprint sensor may be deteriorated. However, according to the present disclosure, the thickness TH1 of the electronic module EM may be smaller than the total thickness TH2 of the first adhesive layer OCA and the cushion layer CSH. The electronic module EM may be spaced apart from the magnetic layer FS and the conductive layer CU in the third direction DR3 that is the thickness direction. Accordingly, the reliability of the electronic module EM may be increased. Thus, the electronic device 1000 with increased reliability may be provided.

The area where the electronic module EM is disposed may be defined as the sensing area SA. When biometric information of the user is provided through the sensing area SA, the electronic module EM may sense the biometric information.

A cutting line CL may be defined in the magnetic layer FS and the conductive layer CU, surrounding the opening OP.

According to the present disclosure, the magnetic layer FS and the conductive layer CU may be stacked such that the magnetic layer FS is closer to the display panel DP than the conductive layer CU. A magnetic field generated from the pen PN (refer to FIG. 5) may be sensed through the sensor layer 200 (refer to FIG. 5). At this time, the magnetic field may be reflected by the magnetic field FS, and thus the sensing reliability of the sensor layer 200 (refer to FIG. 5) may be increased. A magnetic field transmitting through the magnetic layer FS may be blocked by the conductive layer CU. The conductive layer CU may block a magnetic field generated from above the conductive layer CU and a magnetic field generated from below the conductive layer CU and may increase the reliability of a signal. Thus, the electronic device 1000 with increased reliability may be provided.

In addition, according to the present disclosure, in a plan view, the electronic module EM may overlap the magnetic layer FS and the conductive layer CU and might not overlap the first adhesive layer OCA and the cushion layer CSH. The cover panel CP may include the opening OP in which the electronic module EM is disposed. A magnetic field generated from the pen PN (refer to FIG. 5) may be reflected or blocked by the magnetic layer FS and the conductive layer CU. The magnetic layer FS and the conductive layer CU may be disposed under the sensing area SA. Deterioration in the performance of detecting the pen PN (refer to FIG. 5) may be increased. Due to this, the sensing reliability in one area of the sensor layer 200 (refer to FIG. 5) that overlaps the sensing area SA may be increased. Thus, the electronic device 1000 with increased reliability may be provided.

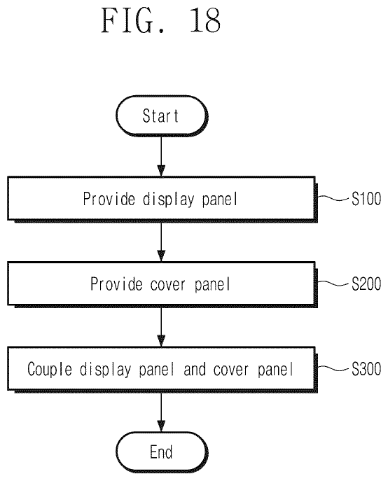

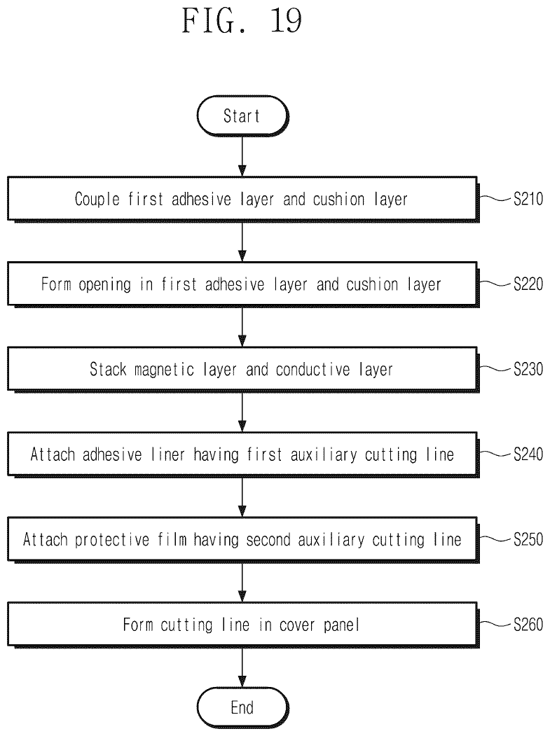

FIG. 18 is a flowchart illustrating a method of manufacturing the electronic device according to an embodiment of the present disclosure, and FIG. 19 is a flowchart illustrating a method of providing the cover panel according to an embodiment of the present disclosure.

Referring to FIGS. 17, 18, and 19, the method of manufacturing the electronic device 1000 may include a step S100 of providing the display panel DP, a step S200 of providing the cover panel CP, and a step S300 of coupling the display panel DP and the cover panel CP.

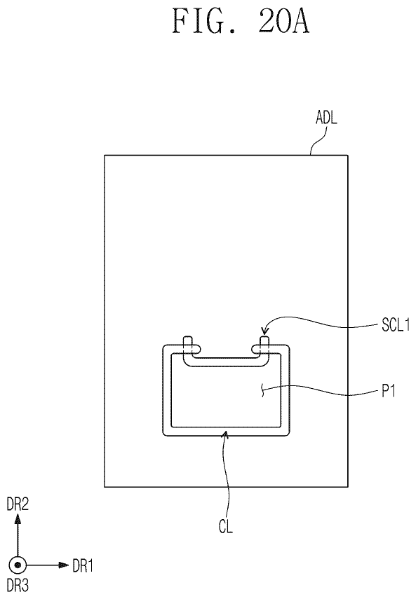

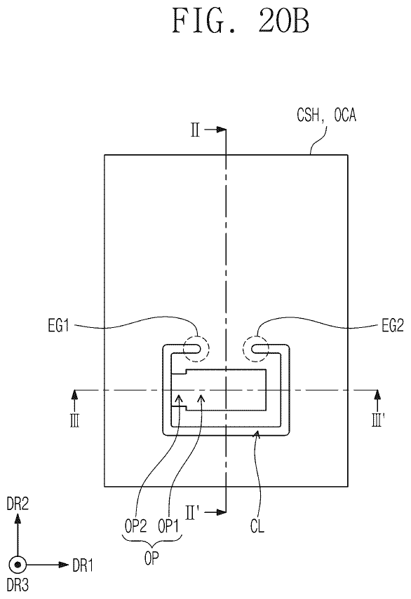

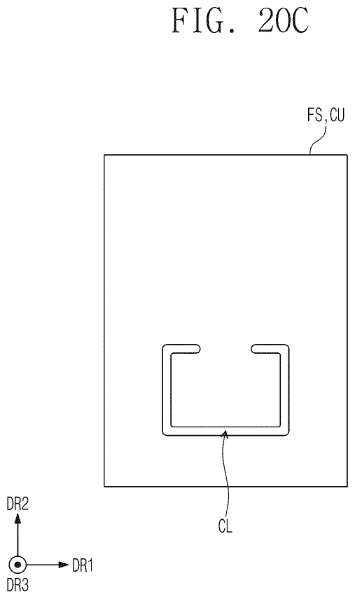

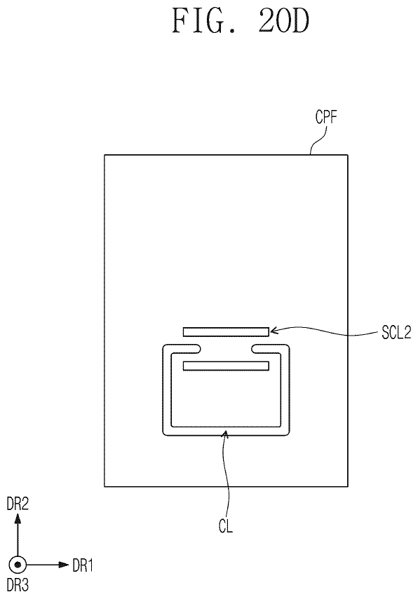

The step S200 of providing the cover panel CP may include a step S210 of coupling the first adhesive layer OCA and the cushion layer CSH, a step S220 of forming the opening OP in the first adhesive layer OCA and the cushion layer CSH, a step S230 of stacking the magnetic layer FS and the conductive layer CU, a step S240 of attaching an adhesive liner ADL (refer to FIG. 20A) in which a first auxiliary cutting line SCL1 (refer to FIG. 20A) is formed, a step S250 of attaching a protective film CPF (refer to FIG. 20D) in which a second auxiliary cutting line SCL2 (refer to FIG. 20D) is formed, and a step S260 of forming the cutting line CL in the cover panel CP.

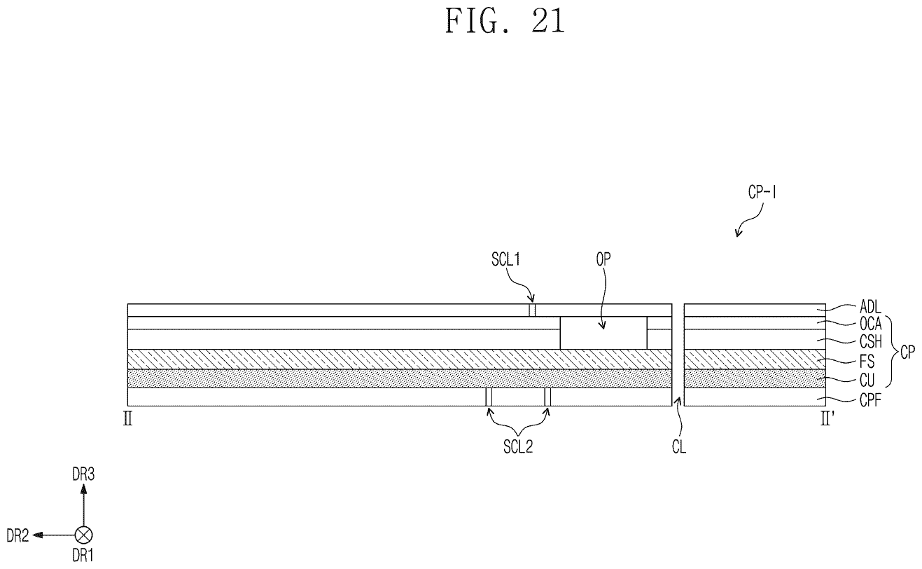

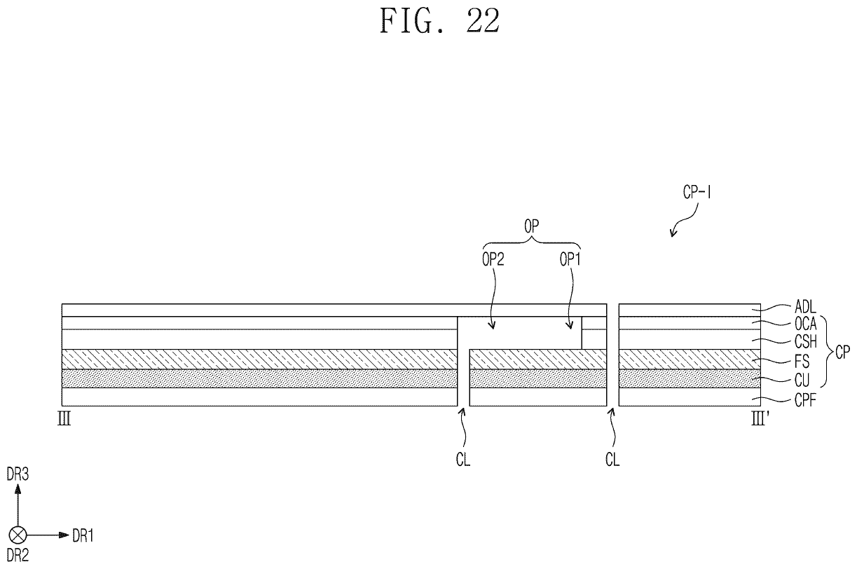

FIG. 20A is a plan view illustrating the adhesive liner according to an embodiment of the present disclosure. FIG. 20B is a plan view of the adhesive layer and the cushion layer according to an embodiment of the present disclosure. FIG. 20C is a plan view of the magnetic layer and the conductive layer according to an embodiment of the present disclosure. FIG. 20D is a plan view of the protective film according to an embodiment of the present disclosure. FIG. 21 is a cross-sectional view of a preliminary cover panel taken along a line corresponding to II-II′ in FIG. 20B according to an embodiment of the present disclosure. FIG. 22 is a cross-sectional view of the preliminary cover panel taken along a line corresponding to III-III′ in FIG. 20B according to an embodiment of the present disclosure.

Referring to FIGS. 18, 19, and 20A to 22, the preliminary cover panel CP-I may include the adhesive liner ADL, the cover panel CP, and the protective film CPF. The cover panel CP may include the first adhesive layer OCA, the cushion layer CSH, the magnetic layer FS, and the conductive layer CU.

The first auxiliary cutting line SCL1 may be formed in the adhesive liner ADL. As the cutting line CL is formed in the cover panel CP, the cutting line CL may also be formed in the adhesive liner ADL.

The first auxiliary cutting line SCL1 may overlap the cutting line CL, in a plan view. For example, the first auxiliary cutting line SCL1 and the cutting line CL may be substantially connected with each other. Due to this, a portion P1 of the adhesive liner ADL may be spaced apart from the rest of the adhesive liner ADL. The adhesive liner ADL may be disposed on the first adhesive layer OCA (refer to FIG. 17). The adhesive liner ADL may be disposed to preserve the adhesive force of the first adhesive layer OCA in the step S200 of providing the cover panel CP.

The adhesive liner ADL may be a component that is removed in a manufacturing process of the electronic device 1000 (refer to FIG. 17).

The opening OP may be formed in the first adhesive layer OCA and the cushion layer CSH. The cutting line CL may surround the opening OP. The opening OP may include a first opening OP1 and a second opening OP2 extending from the first opening OP1 in the direction opposite to the first direction DR1. The width of the first opening OP1 in the second direction DR2 may be greater than the width of the second opening OP2 in the second direction DR2.

The electronic module EM (refer to FIG. 17) may be disposed within the first opening OP1. A circuit board connected to the electronic module EM (refer to FIG. 17) may be disposed within the second opening OP2.

The cutting line CL may be formed in the first adhesive layer OCA and the cushion layer CSH. The second opening OP2 may be in contact with a portion of the cutting line CL.

Opposite ends EG1 and EG2 of the cutting line CL may be spaced apart from each other with a gap interposed therebetween and the opposite ends may face each other. The cutting line CL may have a quadrilateral shape, in a plan view. The opposite ends EG1 and EG2 of the cutting line CL may be defined on one side of the quadrilateral shape, in a plan view. For example, the opposite ends EG1 and EG2 of the cutting line CL may be defined on a long side of the quadrilateral shape. The opposite ends EG1 and EG2 of the cutting line CL may be spaced apart from each other in the first direction DR1.

The cutting line CL, in a plan view, may have an open loop shape in which at least portions are spaced apart from each other due to the opposite ends EG1 and EG2 of the cutting line CL.

The magnetic layer FS and the conductive layer CU may be disposed under the cushion layer CSH. The cutting line CL may be formed in the magnetic layer FS and the conductive layer CU.

The protective film CPF may be disposed under the conductive layer CU. The protective film CPF may be a component that is provided to protect the cover panel CP in the manufacture of the electronic device 1000.

As the cutting line CL is formed in the cover panel CP, the cutting line CL may also be formed in the protective film CPF. The protective film CPF may be a component that is removed in the manufacturing process of the electronic device 1000 (refer to FIG. 17).

The second auxiliary cutting line SCL2 may be formed in the protective film CPF. The second auxiliary cutting line SCL2 may be adjacent to the gap between the opposite ends EG1 and EG2 of the cutting line CL. The second auxiliary cutting line SCL2 may be spaced apart from the cutting line CL in the second direction DR2.

Delamination of the cover panel CP may be facilitated by the second auxiliary cutting line SCL2. The second auxiliary cutting line SCL2 may be provided in plural numbers. The plurality of second auxiliary cutting lines SCL2 may be spaced apart from each other in the second direction DR2.

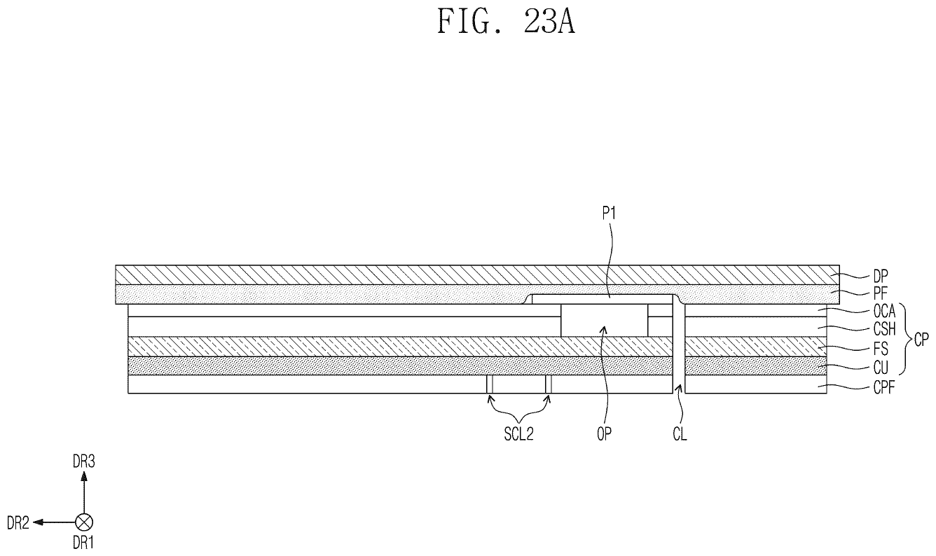

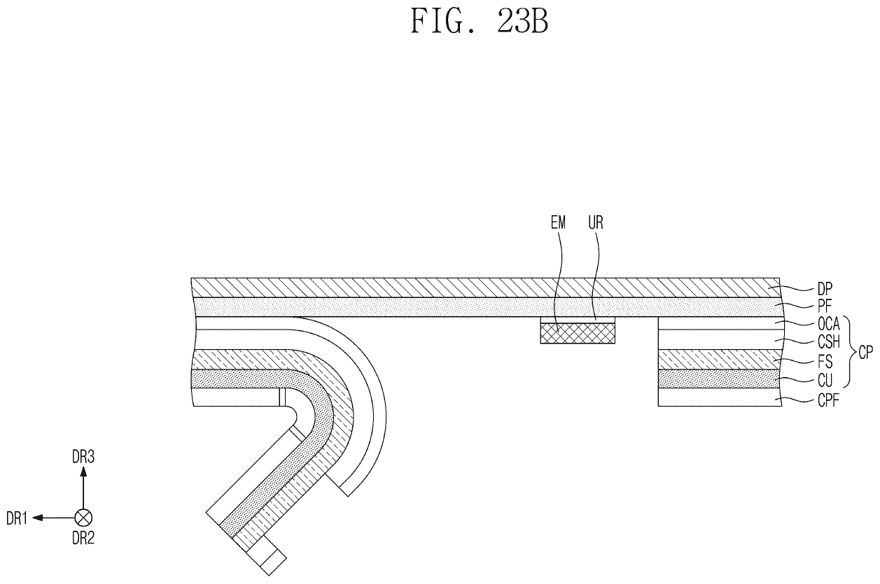

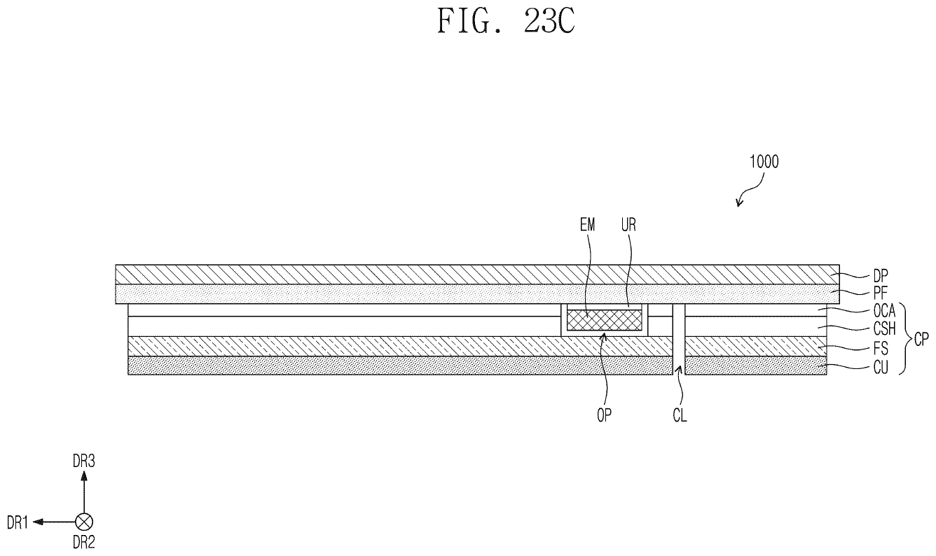

FIG. 23A is a cross-sectional view illustrating part of the step of coupling the display panel and the cover panel according to an embodiment of the present disclosure. In describing FIG. 23A, the components described with reference to FIG. 17 will be assigned with the identical reference numerals, and to the extent that an element is not described in detail with respect to this figure, it may be understood that the element is at least similar to a corresponding element that has been described elsewhere within the present disclosure.

Referring to FIGS. 18 and 23A, the step S300 of coupling the display panel DP and the cover panel CP may include a step of removing a portion of the adhesive liner ADL based on the first auxiliary cutting line SCL1 and the cutting line CL and a step of bonding a portion of the first adhesive layer OCA from which the adhesive liner ADL is removed and the display panel DP.

The first auxiliary cutting line SCL1 of the adhesive liner ADL and the cutting line CL may be connected with each other, in a plan view. Another portion other than the first portion P1 of the adhesive liner ADL may be removed. Due to this, in a plan view, the remaining area of the first adhesive layer OCA other than the area overlapping the first portion P1 may be exposed. The remaining area of the first adhesive layer OCA may be bonded with the display panel DP and the protective layer PF.

FIG. 23B is a cross-sectional view illustrating part of the method of manufacturing the electronic device according to an embodiment of the present disclosure.

Referring to FIGS. 23A and 23B, a portion of the cover panel CP may be delaminated and bent along the cutting line CL.

According to the present disclosure, a portion of the cover panel CP that overlaps the area where the opening OP is defined may be easily delaminated by the first portion P1 of the adhesive liner ADL because the portion of the cover panel CP are not bonded with the first adhesive layer OCA and the protective layer PF. In addition, the portion of the cover panel CP may be easily delaminated in the third direction DR3 by the second auxiliary cutting line SCL2 defined in the protective film CPF. Accordingly, the electronic device 1000 (refer to FIG. 17) with increased reliability may be provided.

The electronic module EM may be attached under the display panel DP and the protective layer PF. Since the portion of the cover panel CP is delaminated, the electronic module EM may be easily attached under the display panel DP. The electronic module EM may be bonded by a second adhesive layer UR. The second adhesive layer UR may be disposed between the electronic module EM and the display panel DP. The second adhesive layer UR may be a component that is bonded in a different manner from the first adhesive layer OCA. For example, the first adhesive layer OCA may include an optical adhesive material, and the second adhesive layer UR may include a UV resin.

The first portion P1 of the adhesive liner ADL may be removed after the electronic module EM is attached.

FIG. 23C is a cross-sectional view illustrating part of the method of manufacturing the electronic device according to an embodiment of the present disclosure. In describing FIG. 23C, the components described with reference to FIGS. 23A and 23BA will be assigned with the identical reference numerals, and to the extent that an element is not described in detail with respect to this figure, it may be understood that the element is at least similar to a corresponding element that has been described elsewhere within the present disclosure.

Referring to FIG. 23C, the portion of the cover panel CP, which is delaminated such that the electronic module EM is accommodated in the opening OP, may be unbent. Since the first portion P1 (refer to FIG. 23A) is removed, the entire upper surface of the first adhesive layer OCA may be bonded to the lower surface of the protective layer PF.

The cutting line CL may surround the opening OP, in a plan view. Due to this, the first adhesive layer OCA may be disposed within the separation space between the cutting line CL and the opening OP. When the delaminated portion of the cover panel CP is unbent, the delaminated portion of the cover panel CP may be easily bonded by the first adhesive layer OCA.

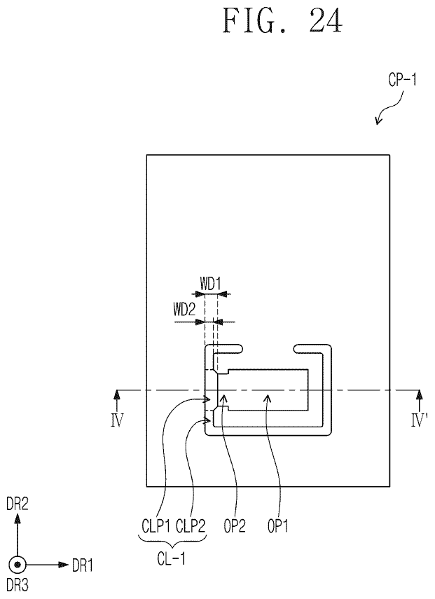

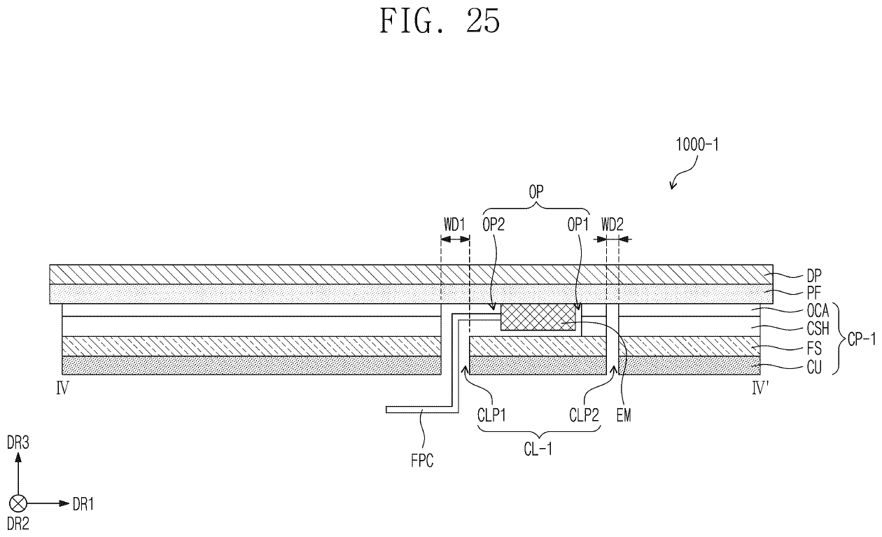

FIG. 24 is a plan view illustrating a cover panel according to an embodiment of the present disclosure, and FIG. 25 is a cross-sectional view of an electronic device taken along a line corresponding to IV-IV′ in FIG. 24 according to an embodiment of the present disclosure.

Referring to FIGS. 24 and 25, a cutting line CL-1 may be defined in the cover panel CP-1. A first portion CLP1 and a second portion CLP2 extending from the first portion CLP1 may be defined in the cutting line CL-1.

An opening OP may be defined in the cover panel CP-1. The opening OP may include a first opening OP1 and a second opening OP2 extending from the first opening OP1 in the direction opposite to the first direction DR1.

The first portion CLP1 may be defined at one end of the second opening OP2. The second portion CLP2 may be spaced apart from the opening OP, in a plan view.

The first width WD1 of the first portion CLP1 may be greater than the second width WD2 of the second portion CLP2.

An electronic module EM may be disposed within the first opening OP1. A circuit board FPC connected to the electronic module EM may be disposed within the second opening OP2. Since the first width WD1 is greater than the second width WD2, the circuit board FPC may be easily disposed below the cover panel CP-1 through the first portion CLP1. The electronic module EM may be connected to the main driver 1000C (refer to FIG. 1) through the circuit board FPC.

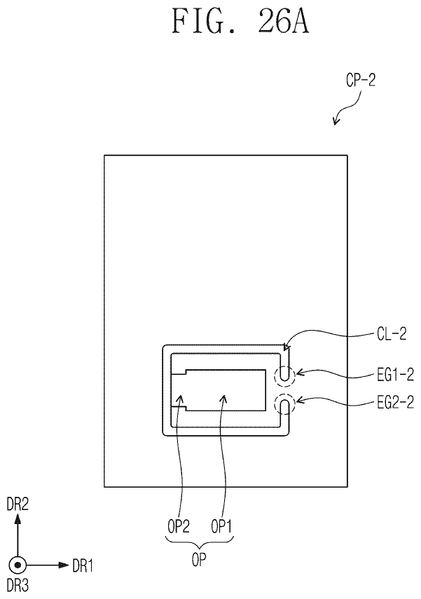

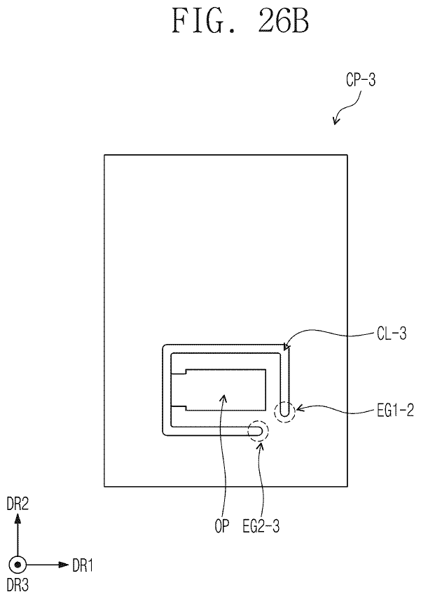

FIG. 26A is a plan view illustrating a cover panel according to an embodiment of the present disclosure.

Referring to FIG. 26A, a cutting line CL-2 may be defined in the cover panel CP-2. Opposite ends EG1-2 and EG2-2 of the cutting line CL-2 may be spaced apart from each other with a gap interposed therebetween and the opposite ends may face each other. The cutting line CL-2 may have a quadrilateral shape, in a plan view. The opposite ends EG1-2 and EG2-2 of the cutting line CL-2 may be defined on one side of the quadrilateral shape, in a plan view. For example, the opposite ends EG1-2 and EG2-2 of the cutting line CL-2 may be defined on a short side of the quadrilateral shape. The opposite ends EG1-2 and EG2-2 of the cutting line CL-2 may be spaced apart from each other in the second direction DR2.

According to the present disclosure, the opposite ends EG1-2 and EG2-2 of the cutting line CL-2 may face a portion of the cutting line CL-2 that is connected with a second opening OP2. Since a first adhesive layer OCA is not disposed within an area adjacent to the portion of the cutting line CL-2, the cover panel CP-2 may be easily delaminated with a small force when the cover panel CP-2 adjacent to the opening OP is delaminated. Accordingly, an electronic device manufacturing method with increased reliability may be provided.

FIG. 26B is a plan view illustrating a cover panel according to an embodiment of the present disclosure.

Referring to FIG. 26B, a cutting line CL-3 may be defined in the cover panel CP-3. Opposite ends EG1-3 and EG2-3 of the cutting line CL-3 may be spaced apart from each other with a gap interposed therebetween and the opposite ends may face each other. The cutting line CL-3 may have a quadrilateral shape, in a plan view. The opposite ends EG1-3 and EG2-3 of the cutting line CL-3 may be defined at vertices of the quadrilateral shape, in a plan view.

According to the present disclosure, the opposite ends EG1-3 and EG2-3 of the cutting line CL-3 may be defined at vertices of the quadrilateral shape. When the cover panel CP-3 adjacent to an opening OP is delaminated, the cover panel CP-3 may be easily delaminated with a small force. Accordingly, an electronic device manufacturing method with increased reliability may be provided.

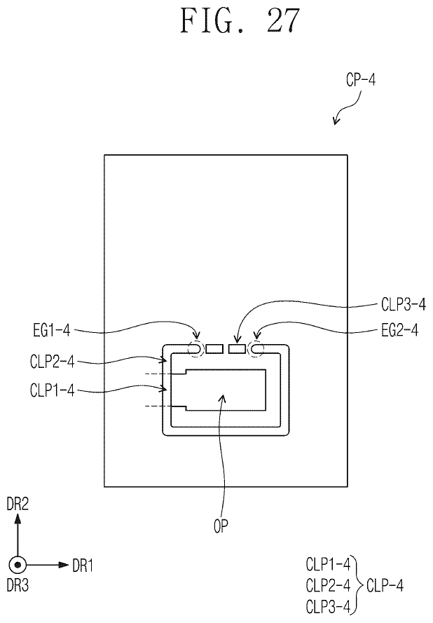

FIG. 27 is a plan view of a cover panel according to an embodiment of the present disclosure.

Referring to FIG. 27, a cutting line CL-4 may be defined in the cover panel CP-4. A first portion CLP1-4, a second portion CLP2-4 extending from the first portion CLP1-4, and a plurality of third portions CLP3-4 may be defined in the cutting line CL-4.

The plurality of third portions CLP3-4 may be adjacent to opposite ends EG1-4 and EG2-4 of the second portion CLP2-4. The plurality of third portions CLP3-4 may be spaced apart from each other in the first direction DR1.

According to the present disclosure, the plurality of third portions CLP3-4 may operate as a perforated line, and thus a portion of the cover panel CP-4 that is adjacent to an opening OP may be easily bent. Accordingly, an electronic device manufacturing method with increased reliability may be provided.

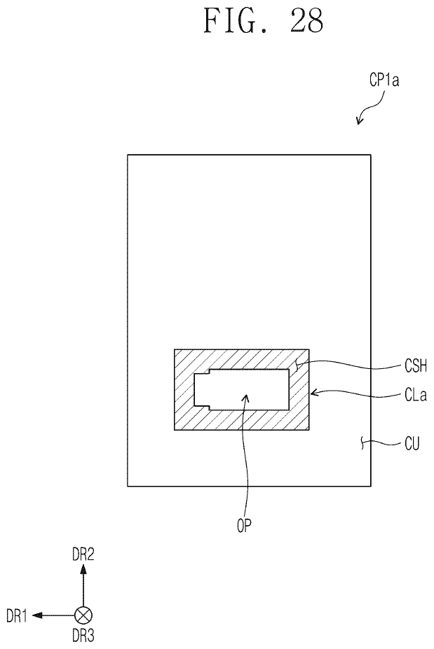

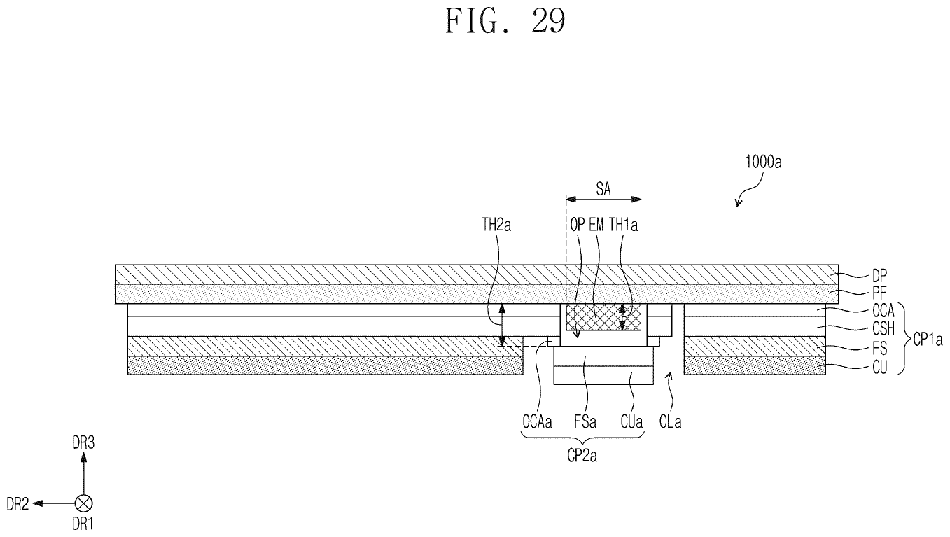

FIG. 28 is a plan view of a first cover panel according to an embodiment of the present disclosure, and FIG. 29 is a cross-sectional view of an electronic device according to an embodiment of the present disclosure. In describing FIG. 29, components identical to the components described with reference to FIG. 17 will be assigned with the identical reference numerals, and to the extent that an element is not described in detail with respect to this figure, it may be understood that the element is at least similar to a corresponding element that has been described elsewhere within the present disclosure.

Referring to FIGS. 28 and 29, an opening OP may be defined in the first cover panel CP1a. A cutting line CLa may be defined in a portion of the first cover panel CP1a. The cutting line CLa may be defined in a magnetic layer FS and a conductive layer CU. The cutting line CLa may surround the opening OP, in a plan view. The cutting line CLa may have a closed-loop shape. Due to this, a portion of the first cover panel CP1a may be removed by the cutting line CLa.

The electronic device 1000a may further include a second cover panel CP2a disposed under an electronic module EM. The second cover panel CP2a may include a first auxiliary adhesive layer OCAa, an auxiliary magnetic layer FSa, and an auxiliary conductive layer CUa.

The first auxiliary adhesive layer OCAa may be disposed under a cushion layer CSH. The first auxiliary adhesive layer OCAa may be disposed between the opening OP and the cutting line CLa, in a plan view. Although FIG. 29 illustrates an example that the thickness of the first auxiliary adhesive layer OCAa is smaller than the thickness of the magnetic layer FS, the thickness of the first auxiliary adhesive layer OCAa according to an embodiment of the present disclosure is not necessarily limited thereto. For example, the thickness of the first auxiliary adhesive layer OCAa may be equal to the thickness of the magnetic layer FS.

The auxiliary magnetic layer FSa may be disposed under the first auxiliary adhesive layer OCAa. The auxiliary magnetic layer FSa may include substantially the same material as the magnetic layer FS.

The auxiliary conductive layer CUa may be disposed under the auxiliary magnetic layer FSa. The auxiliary conductive layer CUa may include substantially the same material as the conductive layer CU.

The second cover panel CP2a may be attached with the first cover panel CP1a after the first cover panel CP1a is attached with a display panel DP and a protective layer PF and the electronic module EM is attached with the display panel DP and the protective layer PF.

When a fingerprint sensor makes contact with another layer unlike in the present disclosure, the reliability of the fingerprint sensor may be deteriorated. However, according to the present disclosure, the thickness TH1a of the electronic module EM may be smaller than the total thickness TH2a of the first adhesive layer OCA, the cushion layer CSH, and the first auxiliary adhesive layer OCAa. The electronic module EM may be spaced apart from the second cover panel CP2a in the third direction DR3 that is the thickness direction. An air gap may be formed between the electronic module EM and the second cover panel CP2a. Accordingly, the reliability of the electronic module EM may be increased. Thus, the electronic device 1000a with increased reliability may be provided.

In addition, according to the present disclosure, the electronic module EM may overlap the auxiliary magnetic layer FSa and the auxiliary conductive layer CUa of the second cover panel CP2a, in a plan view. The auxiliary magnetic layer FSa and the auxiliary conductive layer CUa that are capable of reflecting or blocking a magnetic field generated from the pen PN (refer to FIG. 5) may also be disposed under a sensing area SA. Deterioration in the performance of detecting the pen PN (refer to FIG. 5) may be reduced. Due to this, the sensing reliability in one area of the sensor layer 200 (refer to FIG. 5) that overlaps the sensing area SA may be increased. Thus, the electronic device 1000a with increased reliability may be provided.

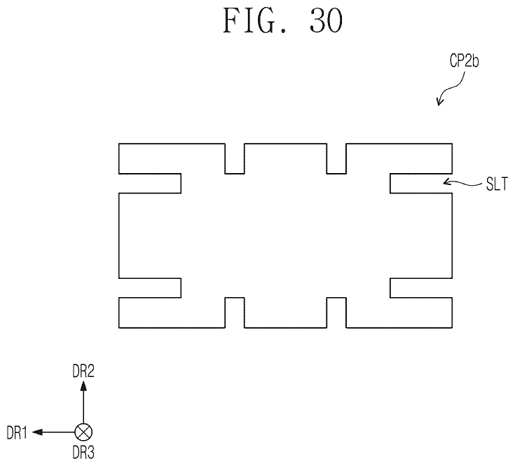

FIG. 30 is a plan view illustrating a second cover panel according to an embodiment of the present disclosure.

Referring to FIG. 30, a plurality of slits SLT may be defined in the second cover panel CP2b, in a plan view. The plurality of slits SLT may be formed on the side surfaces of the second cover panel CP2b.

According to the present disclosure, the electronic module EM may be spaced apart from the second cover panel CP2b in the third direction DR3 that is the thickness direction. An air gap may be formed between the electronic module EM and the second cover panel CP2b. An air path connected with the air gap and the outside of the second cover panel CP2b may be formed by the plurality of slits SLT. In a high-temperature and high-humidity environment, air in the air gap may expand or contract to prevent or eliminate a phenomenon in which the second cover panel CP2b makes contact with the electronic module EM. Accordingly, the electronic device 1000a (refer to FIG. 29) with increased reliability may be provided.

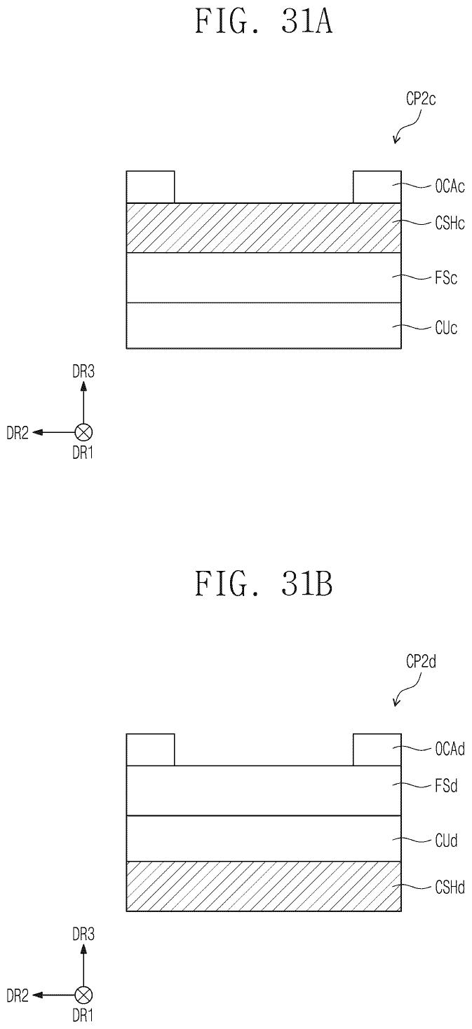

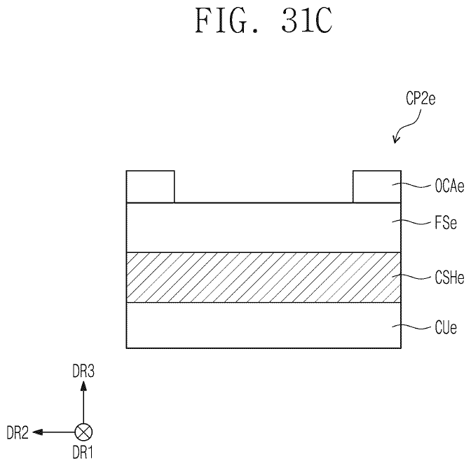

FIG. 31A is a cross-sectional view of a second cover panel according to an embodiment of the present disclosure.

Referring to FIG. 31A, the second cover panel CP2c may include a first auxiliary adhesive layer OCAc, an auxiliary cushion layer CSHc, an auxiliary magnetic layer FSc, and an auxiliary conductive layer CUc. The second cover panel CP2c may have a structure in which the first auxiliary adhesive layer OCAc, the auxiliary cushion layer CSHc, the auxiliary magnetic layer FSc, and the auxiliary conductive layer CUc are sequentially stacked.

The auxiliary cushion layer CSHc may have a physical property that is not affected by an electromagnetic field. The auxiliary cushion layer CSHc may include substantially the same material as the cushion layer CSH.

According to the present disclosure, the auxiliary cushion layer CSHc may compensate for the level difference and surface quality of the second cover panel CP2c and may prevent the second cover panel CP2c from being curved in one direction. Accordingly, the electronic device 1000a (refer to FIG. 29) with increased reliability may be provided.

FIG. 31B is a cross-sectional view of a second cover panel according to an embodiment of the present disclosure.

Referring to FIG. 31B, the second cover panel CP2d may include a first auxiliary adhesive layer OCAd, an auxiliary cushion layer CSHd, an auxiliary magnetic layer FSd, and an auxiliary conductive layer CUd. The second cover panel CP2d may have a structure in which the first auxiliary adhesive layer OCAd, the auxiliary magnetic layer FSd, the auxiliary conductive layer CUd, and the auxiliary cushion layer CSHd are sequentially stacked.

According to the present disclosure, the auxiliary magnetic layer FSd and the auxiliary conductive layer CUd may be stacked such that the auxiliary magnetic layer FSd is closer to the display panel DP than the auxiliary conductive layer CUd. A magnetic field generated from the pen PN (refer to FIG. 5) may be sensed through the sensor layer 200 (refer to FIG. 5). At this time, the magnetic field may be reflected by the auxiliary magnetic field FSd, and thus the sensing reliability of the sensor layer 200 (refer to FIG. 5) may be increased. A magnetic field transmitting through the auxiliary magnetic layer FSd may be blocked by the auxiliary conductive layer CUd. The auxiliary conductive layer CUd may block a magnetic field generated from above the auxiliary conductive layer CUd and a magnetic field generated from below the auxiliary conductive layer CUd and may increase the reliability of a signal. Thus, the electronic device 1000a with increased reliability may be provided.

FIG. 31C is a cross-sectional view of a second cover panel according to an embodiment of the present disclosure.

Referring to FIG. 31C, the second cover panel CP2e may include a first auxiliary adhesive layer OCAe, an auxiliary cushion layer CSHe, an auxiliary magnetic layer FSe, and an auxiliary conductive layer CUe. The second cover panel CP2e may have a structure in which the first auxiliary adhesive layer OCAe, the auxiliary magnetic layer FSe, the auxiliary cushion layer CSHe, and the auxiliary conductive layer CUe are sequentially stacked.

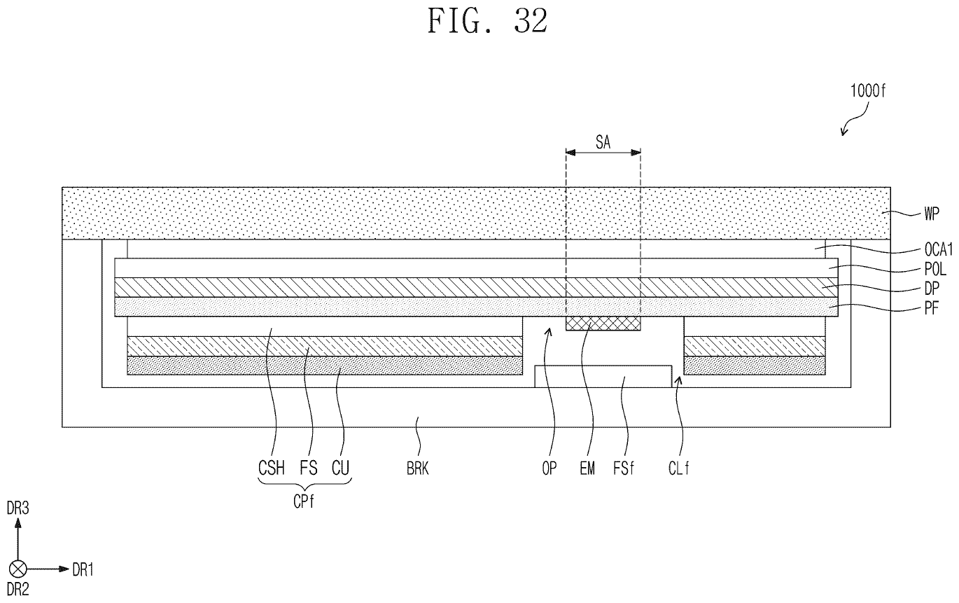

FIG. 32 is a cross-sectional view of an electronic device according to an embodiment of the present disclosure. In describing FIG. 32, components identical to the components described with reference to FIG. 17 will be assigned with the identical reference numerals, and to the extent that an element is not described in detail with respect to this figure, it may be understood that the element is at least similar to a corresponding element that has been described elsewhere within the present disclosure.

Referring to FIG. 32, an opening OP may be defined in a cover panel CPf. A cutting line CLf may be defined in the cover panel CPf. The cutting line CLf may be defined in a magnetic layer FS and a conductive layer CU. The cutting line CLf may surround the opening OP, in a plan view. For example, the cutting line CLf may have the same width as the opening OP. The cutting line CLf may have a closed-loop shape. Due to this, a portion of the cover panel CPf may be removed by the cutting line CLf.

The electronic device 1000f may further include an electrically conductive bracket BRK and an auxiliary magnetic layer FSf that is disposed on the bracket BRK and that overlaps an electronic module EM, in a plan view.

The bracket BRK may be coupled with a window WP and may protect internal components. The bracket BRK may shield a magnetic field.

The auxiliary magnetic layer FSf may include substantially the same material as the magnetic layer FS.

The auxiliary magnetic layer FSf may be spaced apart from the electronic module EM in the third direction DR3.

According to the present disclosure, the electronic module EM may overlap the auxiliary magnetic layer FSf and the bracket BRK, in a plan view. The auxiliary magnetic layer FSf and the bracket BRK that are capable of reflecting or blocking a magnetic field generated from the pen PN (refer to FIG. 5) may also be disposed under a sensing area SA. Deterioration in the performance of detecting the pen PN (refer to FIG. 5) may be reduced. Due to this, the sensing reliability in one area of the sensor layer 200 (refer to FIG. 5) that overlaps the sensing area SA may be increased. Accordingly, the electronic device 1000f with increased reliability may be provided.

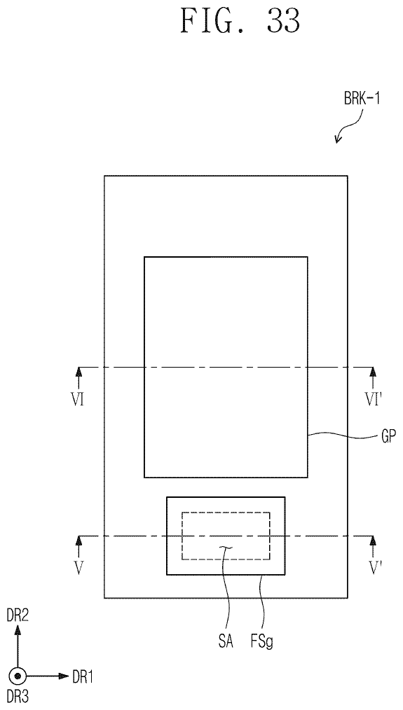

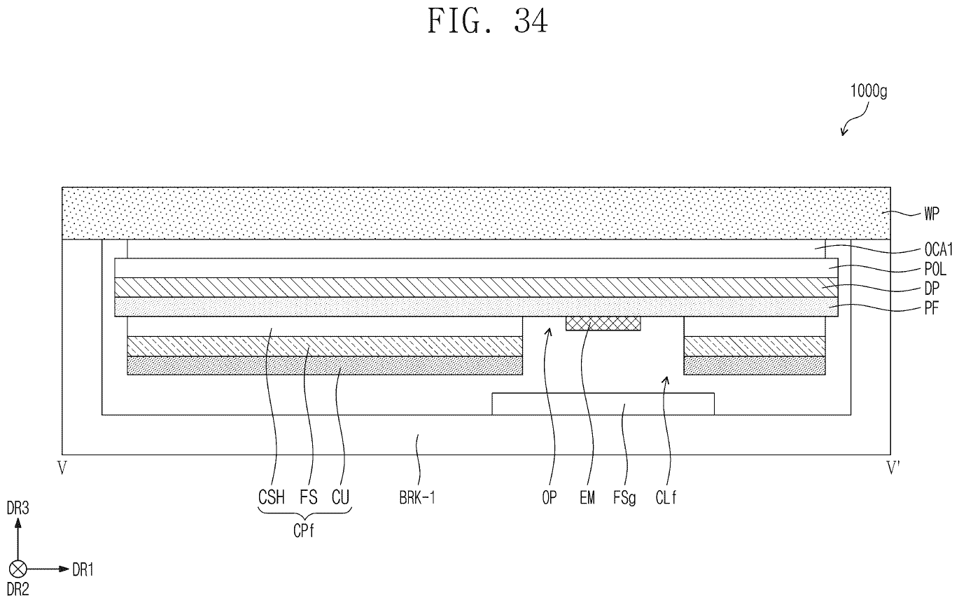

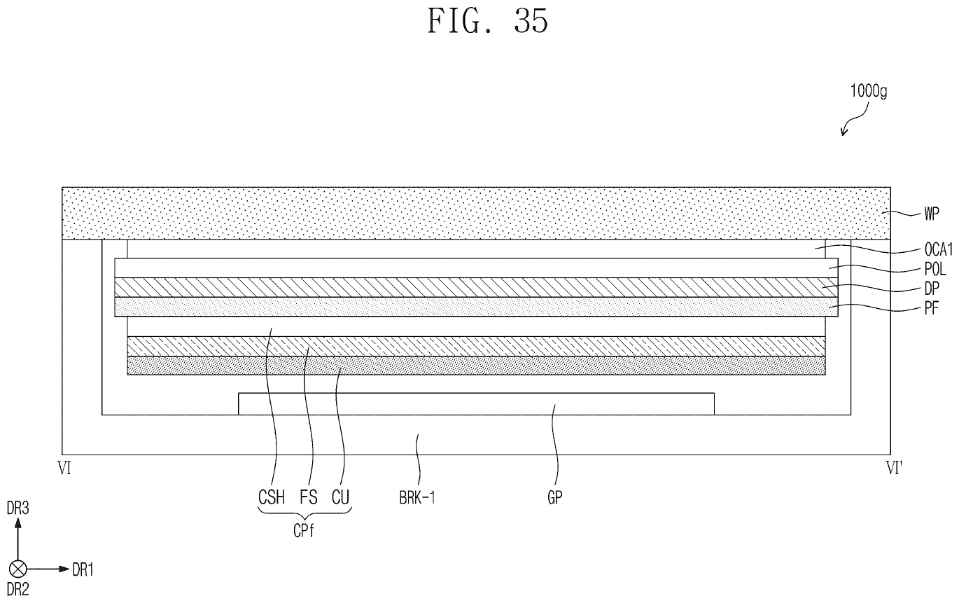

FIG. 33 is a plan view illustrating a bracket according to an embodiment of the present disclosure. FIG. 34 is a cross-sectional view of an electronic device taken along a line corresponding to V-V′ in FIG. 33 according to an embodiment of the present disclosure. FIG. 35 is a cross-sectional view of the electronic device taken along a line corresponding to VI-VI′ in FIG. 33 according to an embodiment of the present disclosure. In describing FIGS. 34 and 35, components identical to the components described with reference to FIG. 32 will be assigned with the identical reference numerals, and to the extent that an element is not described in detail with respect to this figure, it may be understood that the element is at least similar to a corresponding element that has been described elsewhere within the present disclosure.

Referring to FIGS. 33 to 35, the electronic device 1000g may further include a heat radiating layer GP. An auxiliary magnetic layer FSg and the heat radiating layer GP may be disposed on the upper surface of the bracket BRK-1.

The auxiliary magnetic layer FSg may overlap a cover panel CPf, in a plan view. As the auxiliary magnetic layer FSg covers an electronic module EM, in a plan view, vulnerable portions such as external noise and moisture may be compensated for.

The heat radiating layer GP may be disposed under a display panel DP. The heat radiating layer GP may induce the release of heat generated from the electronic device 1000g. For example, the heat radiating layer GP may be a graphite sheet.

The main driver 1000c (refer to FIG. 1) and the power supply module 1500 (refer to FIG. 1) may be disposed under one area of the bracket BRK-1 that overlaps the heat radiating layer GP.

As described above, the current path having the loop coil pattern may be implemented by the components included in the sensor layer. Accordingly, the electronic device may charge the pen using the sensor layer. Thus, a component having a coil for charging the pen does not need to be separately added so that an increase in the thickness and weight of the electronic device and a decrease in the flexibility of the electronic device might not occur.

In addition, as described above, in a plan view, the electronic module may overlap the magnetic layer and the conductive layer and might not overlap the first adhesive layer and the cushion layer. The cover panel may include the opening in which the electronic module is disposed. The magnetic layer and the conductive layer that are capable of reflecting or blocking the magnetic field generated from the pen may also be disposed under the sensing area. Accordingly, deterioration in the performance of detecting the pen may be reduced. Due to this, the sensing reliability in one area of the sensor layer that overlaps the sensing area may be increased. Thus, the electronic device and the electronic device manufacturing method with increased reliability may be provided.

While the present disclosure has been described with reference to embodiments thereof, it will be apparent to those of ordinary skill in the art that various changes and modifications may be made thereto without departing from the spirit and scope of the present disclosure.

What is claimed is:

1. An electronic device, comprising:
a display panel;
a first cover panel disposed under the display panel; and
an electronic module disposed under the display panel,
wherein the first cover panel includes:
a first adhesive layer disposed under the display panel;
a cushion layer disposed under the first adhesive layer;
a magnetic layer disposed under the cushion layer; and
a conductive layer disposed under the magnetic layer,
wherein the first adhesive layer and the cushion layer together include an opening, and the electronic module is disposed within the opening, and
wherein a cutting line is defined in the magnetic layer and the conductive layer, surrounding the opening.

2. The electronic device of claim 1, wherein the magnetic layer and the conductive layer each cover the electronic module, in a plan view.

3. The electronic device of claim 1, wherein the electronic module is spaced apart from both the magnetic layer and the conductive layer in a thickness direction.

4. The electronic device of claim 1, wherein opposite ends of the cutting line are spaced apart from each other with a gap interposed therebetween such that the opposite ends face each other.

5. The electronic device of claim 4, wherein the cutting line has a quadrilateral shape, in a plan view.

6. The electronic device of claim 5, wherein the opposite ends of the cutting line are defined on one side of the quadrilateral shape, in a plan view.

7. The electronic device of claim 5, wherein the opposite ends of the cutting line are defined at vertices of the quadrilateral shape, in a plan view.

8. The electronic device of claim 1, wherein a first portion and a second portion extend from the first portion are defined in the cutting line,
wherein the first portion is defined at one end of the opening when viewed in a first direction, and
wherein the second portion is spaced apart from the opening when viewed in a second direction crossing the first direction.

9. The electronic device of claim 8, wherein a first width of the first portion is greater than a second width of the second portion.

10. The electronic device of claim 8, wherein a plurality of third portions adjacent to opposite ends of the second portion are additionally defined in the cutting line, and
wherein the plurality of third portions are spaced apart from each other in the first direction.

11. The electronic device of claim 1, wherein the electronic module includes a fingerprint sensor.

12. The electronic device of claim 1, wherein the electronic module includes a speaker or a photo sensor.

13. The electronic device of claim 1, wherein in a plan view, the electronic module overlaps both the magnetic layer and the conductive layer and does not overlap either the first adhesive layer or the cushion layer.

14. The electronic device of claim 1, further comprising:
a second adhesive layer disposed between the display panel and the electronic module and bonded in a different manner from that of the first adhesive layer,
wherein the first adhesive layer includes an optical adhesive material, and
wherein the second adhesive layer includes a UV resin.

15. The electronic device of claim 1, wherein the display panel includes a display layer and a sensor layer disposed on the display layer, and
wherein the sensor layer includes:
a plurality of first electrodes arranged in a first direction and extending in a second direction crossing the first direction;
a plurality of second electrodes arranged in the second direction and extending in the first direction;
a plurality of first auxiliary electrodes arranged in the first direction and extending in the second direction and overlapping the plurality of first electrodes; and
a plurality of second auxiliary electrodes arranged in the second direction and extending in the first direction and overlapping the plurality of second electrodes.

16. The electronic device of claim 1, wherein the cutting line has a closed-loop shape,
wherein the electronic device further comprises a second cover panel disposed under the electronic module, and
wherein the second cover panel includes:
a first auxiliary adhesive layer disposed between the opening and the cutting line, in a plan view;
an auxiliary magnetic layer disposed under the first auxiliary adhesive layer; and
an auxiliary conductive layer disposed under the auxiliary magnetic layer.

17. The electronic device of claim 16, wherein a total thickness of the first adhesive layer, the cushion layer, and the first auxiliary adhesive layer is greater than a thickness of the electronic module.

18. The electronic device of claim 16, wherein a plurality of slits are defined in the second cover panel, in a plan view, and
wherein the plurality of slits are formed on side surfaces of the second cover panel.

19. The electronic device of claim 16, wherein the second cover panel further includes an auxiliary cushion layer disposed under the first auxiliary adhesive layer.

20. The electronic device of claim 1, wherein the cutting line has a closed-loop shape, and
wherein the electronic device further comprises an electrically conductive bracket and an auxiliary magnetic layer disposed on the bracket and overlapping the electronic module, in a plan view.

21. The electronic device of claim 20, wherein the auxiliary magnetic layer overlaps the cover panel, in a plan view.

22. The electronic device of claim 20, further comprising:
a heat radiating layer disposed on the bracket and under the display panel.

23. A method for manufacturing an electronic device, the method comprising:
providing a display panel;
providing a cover panel; and
coupling the display panel and the cover panel to one another,
wherein the providing of the cover panel includes:
coupling a first adhesive layer and a cushion layer to one another;
forming an opening in both the first adhesive layer and the cushion layer;
stacking a magnetic layer and a conductive layer under the cushion layer;
attaching, on the first adhesive layer, an adhesive liner having a first auxiliary cutting line formed therein;
attaching, under the conductive layer, a protective film having a second auxiliary cutting line formed therein; and
forming a cutting line in the cover panel.

24. The method of claim 23, wherein in a plan view, the first auxiliary cutting line is connected to the cutting line forming a closed loop.

25. The method of claim 23, wherein opposite ends of the cutting line are spaced apart from each other with a gap interposed therebetween and the opposite ends face each other.

26. The method of claim 25, wherein in a plan view, the second auxiliary cutting line is adjacent to the gap and spaced apart from the cutting line.

27. The method of claim 23, wherein the coupling of the display panel and the cover panel to one another includes:
removing a portion of the adhesive liner based on the first auxiliary cutting line and the cutting line; and
bonding a portion of the first adhesive layer from which the adhesive liner is removed and the display panel to one another.

28. The method of claim 27, further comprising:
delaminating and bending a portion of the cover panel along the cutting line;
attaching an electronic module under the display panel;
removing the rest of the adhesive liner;
unbending the portion of the cover panel such that the electronic module is accommodated in the opening; and
bonding the rest of the first adhesive layer and the display panel.
